(19) United States
(12) Patent Application Publication
(10) Pub. No.: US 2026/0286192 A1
(43) Pub. Date: Sep. 24, 2026

(54) ADHESIVE FILM FOR CIRCUIT CONNECTION, CIRCUIT CONNECTION STRUCTURE, AND METHOD FOR PRODUCING SAME

(71) Applicant: Resonac Corporation, Minato-ku, Tokyo (JP)

(72) Inventors: Takashi NAKAZAWA, Tokyo (JP); Masato FUKUI, Tokyo (JP); Kazuya NARITOMI, Tokyo (JP); Takayuki ICHIMURA, Tokyo (JP); Tomoki TAKAYAMA, Tokyo (JP)

(21) Appl. No.: 19/473,731

(22) PCT Filed: Apr. 9, 2024
(86) PCT No.: PCT/JP2024/014419

§ 371 Date: Oct. 8, 2025

(30) Foreign Application Priority Data
Apr. 13, 2023 (JP) 2023-065696

(51) Int. Cl. C09J 7/30; C09J 9/02; C09J 163/00; H05K 1/14

(52) U.S. Cl. CPC C09J 7/30; C09J 9/02; C09J 163/00; H05K 1/144; C09J 2203/326; C09J 2301/408; C09J 2301/50

(57) ABSTRACT

An adhesive film for circuit connection includes a thermosetting resin component and electroconductive particles, and the thermosetting resin component contains a fluorene skeleton-containing epoxy resin represented by the following general formula (1) and an epoxy resin thermosetting agent.

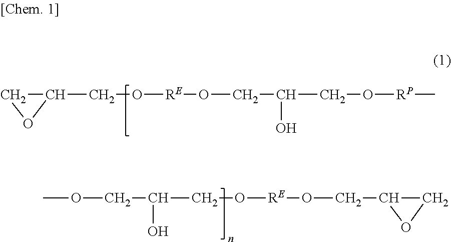

in the formula (1), R^{E} is a skeleton residue derived from an epoxy resin, R^{P} is a skeleton residue derived from a phenol compound having a fluorene skeleton, and n represents the number of repetitions.

### TECHNICAL FIELD

The present invention relates to an adhesive film for circuit connection, a circuit connection structure, and a method for producing the same.

### BACKGROUND ART

In recent years, in the display industry, a paradigm shift from a liquid crystal display to an organic LED (Light Emitting Diode) has occurred in a module of a display means, and accordingly, a constituent material of a panel has changed.

In a conventional liquid crystal display, a glass substrate is used as a substrate, a metal such as aluminum is used for a bottom layer circuit as a circuit material formed on the glass substrate, and ITO (Indium Tin Oxide) or the like is used for a surface layer electrode. On the other hand, in an organic LED, a plastic substrate having flexibility such as a polyimide substrate is used as a substrate, and the use of Ti as a circuit material formed on the plastic substrate has become mainstream. A pressure-sensitive adhesive layer and a flexible member such as a polyethylene terephthalate (PET) substrate are usually disposed on the lower surface of the polyimide substrate for the purpose of imparting flexibility (see, for example, Patent Literature 1).

Meanwhile, in a liquid crystal display, so-called COG (chip on glass) mounting in which various electronic components such as a driver IC are directly mounted on a glass substrate of a display panel has been adopted from the viewpoints of fine pitch implementation, weight reduction and thickness reduction, and the like. As a COG mounting method, for example, a method of obtaining a circuit connection structure by thermocompression bonding a liquid crystal driver IC onto a glass substrate via an adhesive film for circuit connection having anisotropic electroconductivity in which electroconductive particles are dispersed in an adhesive is utilized.

### CITATION LIST

### Patent Literature

Patent Literature 1: Japanese Unexamined Patent Publication No. 2016-054288

### SUMMARY OF INVENTION

### Technical Problem

In recent years, the market demand level for reliability of panel quality has been increasing. In order to improve reliability, it is required that the mounted body has HAST resistance such that the connection resistance is unlikely to increase even after a severe test such as HAST (Highly Accelerated Stress Test).

A main object of the present invention is to provide an adhesive film for circuit connection which is used for connection between circuit members and can provide a circuit connection structure having sufficient HAST resistance in stabilizing the connection resistance between opposing electrodes.

### Solution to Problem

In order to solve the above problem, one aspect of the present invention provides an adhesive film for circuit connection including a thermosetting resin component and electroconductive particles, and the thermosetting resin component contains a fluorene skeleton-containing epoxy resin represented by the following general formula (1) and an epoxy resin thermosetting agent.

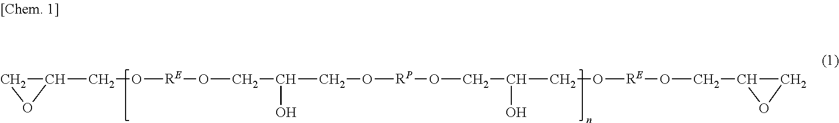

In the formula (1), R^{E} is a skeleton residue derived from an epoxy resin, R^{P} is a skeleton residue derived from a phenol compound having a fluorene skeleton, and n represents the number of repetitions.

According to this adhesive film for circuit connection, it is possible to obtain a circuit connection structure having sufficient HAST resistance in stabilizing the connection resistance between opposing electrodes by connecting circuit members to each other. The reason why such an effect is obtained is not necessarily clear, but the present inventors infer as follows. It is considered that since the adhesive film for circuit connection contains a fluorene skeleton-containing epoxy resin having the above-described specific structure and an epoxy resin thermosetting agent, sufficient fluidity is ensured during connection by thermocompression bonding circuit members to fill voids between electrodes, and the rigid structure by the fluorene skeleton can maintain the elastic modulus of the cured product after connection, so that the HAST resistance can be improved.

The fluorene skeleton-containing epoxy resin may have a weight average molecular weight of 5000 to 8000.

The fluorene skeleton-containing epoxy resin may have a softening point of 85 to 105° C.

Meanwhile, COP (chip on plastic) mounting in which a driver IC or the like is directly mounted on a plastic substrate is also being adopted in organic LEDs. However, when excessive pressure is applied to a plastic substrate, problems may arise as defects accompanying deformation of the plastic substrate, such as deformation of a Ti circuit provided on a polyimide substrate, causing cracking and disconnection. Therefore, in COG mounting using an adhesive film for circuit connection, it is usual to apply a pressure of 50 to 100 MPa calculated on an area basis at a bump electrode of an IC chip, but in COP mounting in an organic LED, for example, mounting with a low pressure of 40 MPa or less is considered to be preferable in order to prevent disconnection of a circuit. In the mounted body produced under such a low pressure condition, the connection resistance between the opposing electrodes tends to increase, and it tends to be difficult to obtain sufficient conduction characteristics.

When the fluorene skeleton-containing epoxy resin has the above-described molecular weight and/or softening point, conduction between the opposing electrodes of the circuit connection structure is easily ensured even when the circuit members are connected to each other by a low pressure. Further, when the adhesive film for circuit connection is formed into a reel product, transferability to the circuit member can be improved.

The electroconductive particles may be unevenly distributed on one surface side of the film. In this case, it is easy to improve the capture efficiency of the electroconductive particles during circuit connection.

Another aspect of the present invention provides an adhesive film for circuit connection including a first adhesive layer containing electroconductive particles, a cured product of a photocurable resin component, and a first thermosetting resin component, and a second adhesive layer provided on the first adhesive layer and containing a second thermosetting resin component. In the adhesive film for circuit connection, the second thermosetting resin component contains a fluorene skeleton-containing epoxy resin represented by the following general formula (1) and an epoxy resin thermosetting agent.

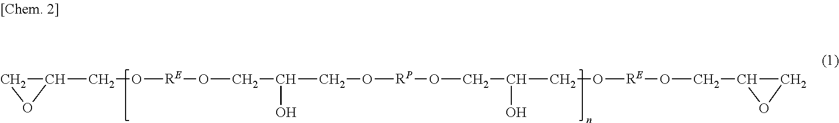

In the formula (1), R^{E} is a skeleton residue derived from an epoxy resin, R^{P} is a skeleton residue derived from a phenol compound having a fluorene skeleton, and n represents the number of repetitions.

According to this adhesive film for circuit connection, it is possible to obtain a circuit connection structure having sufficient HAST resistance in stabilizing the connection resistance between opposing electrodes by connecting circuit members to each other. In addition, in the adhesive film for circuit connection, since the first adhesive layer containing electroconductive particles contains a cured product of a photocurable resin component, the flow of the electroconductive particles during circuit connection can be suppressed, the flowing electroconductive particles can be prevented from bridging between adjacent circuits and reducing insulation properties, and the capture efficiency of the electroconductive particles can be further enhanced.

In the adhesive film for circuit connection according to another aspect, the fluorene skeleton-containing epoxy resin may have a weight average molecular weight of 5000 to 8000.

The fluorene skeleton-containing epoxy resin may have a softening point of 85 to 105° C.

When the fluorene skeleton-containing epoxy resin has the above-described molecular weight and/or softening point, conduction between the opposing electrodes of the circuit connection structure is easily ensured even when the circuit members are connected to each other by a low pressure. Further, when the adhesive film for circuit connection is formed into a reel product, transferability to the circuit member can be improved.

Another aspect of the present invention provides a method for producing a circuit connection structure, the method including steps of: interposing the adhesive film for circuit connection between a first circuit member having a first electrode and a second circuit member having a second electrode; and thermocompression bonding the first circuit member and the second circuit member to electrically connect the first electrode and the second electrode to each other.

Another aspect of the present invention provides a circuit connection structure including a first circuit member having a first electrode, a second circuit member having a second electrode, and a circuit connection portion disposed between the first circuit member and the second circuit member and configured to electrically connect the first electrode and the second electrode to each other, wherein the circuit connection portion includes a cured product of the adhesive film for circuit connection.

### Advantageous Effects of Invention

According to the present invention, it is possible to provide an adhesive film for circuit connection which is used for connection between circuit members and can provide a circuit connection structure having sufficient HAST resistance in stabilizing the connection resistance between opposing electrodes. Further, according to the present invention, it is possible to provide a circuit connection structure obtained using the adhesive film for circuit connection and a method for producing the same.

### BRIEF DESCRIPTION OF DRAWINGS

FIG. 1 is a schematic cross-sectional view showing one embodiment of an adhesive film for circuit connection.

FIG. 2 is a schematic cross-sectional view showing one embodiment of a circuit connection structure.

FIG. 3 is a schematic cross-sectional view showing one embodiment of a method for producing a circuit connection structure.

FIGS. 3(a) and 3(b) are schematic cross-sectional views showing each step.

### DESCRIPTION OF EMBODIMENTS

In the present description, the “(meth)acrylate” means at least one of an acrylate and a methacrylate corresponding thereto. The same applies to other similar expressions such as “(meth)acryloyl” and “(meth)acrylic acid”. As for the materials exemplified below, one type may be used alone or two or more types may be used in combination unless otherwise specified. When a plurality of materials corresponding to the respective components are present in the composition, a content of each component in the composition means the total amount of the plurality of materials present in the composition unless otherwise specified. A numerical range using “to” indicates a range including numerical values described before and after “to” as a minimum value and a maximum value. “A or B” may include either A or B, and may include both A and B. “Normal temperature” means 25° C.

In numerical ranges described in stages in the present description, an upper limit value or a lower limit value of a numerical range in a certain stage may be replaced with an upper limit value or a lower limit value of a numerical range in another stage. In addition, in the numerical range described in the present description, the upper limit value or the lower limit value of the numerical range may be replaced with a value illustrated in the examples.

### [Adhesive Film for Circuit Connection]

An adhesive film for circuit connection of the present embodiment includes a thermosetting resin component and electroconductive particles, and the thermosetting resin component contains a fluorene skeleton-containing epoxy resin (hereinafter also referred to as component (C-F)) represented by the following general formula (1) and an epoxy resin thermosetting agent.

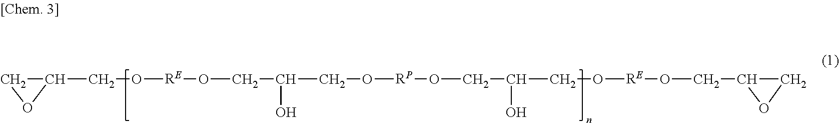

In the formula (1), R^{E} is a skeleton residue derived from an epoxy resin, R^{P} is a skeleton residue derived from a phenol compound having a fluorene skeleton, and n represents the number of repetitions.

The electroconductive particles may be unevenly distributed on one surface side of the film. In this case, the adhesive film for circuit connection may include a region P containing a thermosetting resin component and a cured product of a photocurable resin component in a thickness direction of the film, and electroconductive particles may be dispersed in the region P (the electroconductive particles may be disposed apart from each other in a direction in which the film spreads). The adhesive film for circuit connection may have a region S provided adjacent to the region P and containing a thermosetting resin component containing the component (C-F) and an epoxy resin thermosetting agent. The region S need not contain the cured product of the photocurable resin component and the electroconductive particles.

First, the component (C-F) will be described.

The component (C-F) can contain a bisphenol fluorene skeleton represented by the following general formula (2).

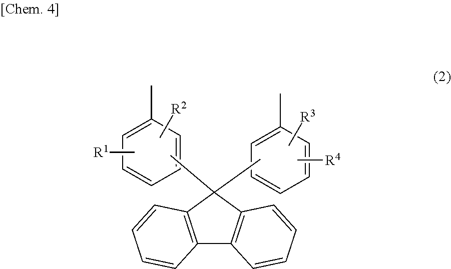

In the formula (2), R¹, R², R³, and R⁴ are each independently a hydrogen atom or a hydrocarbon group having 1 to 8 carbon atoms, and may include a cyclic structure.

The content of the skeleton may be 15 to 70 mol %, 30 to 70 mol %, 20 to 60 mol %, or 30 to 50 mol %. This content can be determined as the total mol % of R^{P} and R^{E} having a bisphenol fluorene skeleton with respect to the total of R^{P} and R^{E} in the general formula (1). The content can also be determined from the types and blending amounts of raw materials when the component (C-F) is produced.

The epoxy equivalent of the component (C-F) may be 700 to 1500 g/eq. 750 to 1400 g/eq, 800 to 1200 g/eq, or 900 to 1100 g/eq. Here, the epoxy equivalent is the number of grams (g/eq) of a resin containing 1 gram equivalent of an epoxy group, and is measured according to the method specified in JIS K-7236.

The component (C-F) may have a weight average molecular weight of 5000 to 8000 from the viewpoint of obtaining HAST resistance even under low-pressure mounting and from the viewpoint of transferability.

In the present description, the weight average molecular weight of the fluorene skeleton-containing epoxy resin means a weight average molecular weight measured under the following conditions using gel permeation chromatography (GPC).
Detector: L-2490-RI manufactured by Hitachi High-Tech Science Corporation
Column: Gelpack GL-R440+R450+R400M
Flow rate: 2.05 ml/min
Concentration: 5 mg/ml
Injection amount: 200 μl
Column temperature: 40° C.
Eluent: THF
Standard sample: polystyrene

The component (C-F) may have a softening point of 100 to 150° C. from the viewpoint of obtaining HAST resistance even under low-pressure mounting and from the viewpoint of transferability.

In the present description, the softening point of the fluorene skeleton-containing epoxy resin means a softening point measured under the following conditions using a thermomechanical analyzer (TMA).
Thermomechanical analyzer: TMA-7100 manufactured by Hitachi High-Tech Science Corporation, Penetration (needle insertion, Φ1 mm) mode
Heating rate: 10° C./min
Load: 98.1 mN

The component (C-F) can be produced by a method in which a phenol compound and a difunctional epoxy resin are allowed to react in the presence of a catalyst (see, for example, Japanese Unexamined Patent Publication No. 2015-178592).

The phenol compound used as a raw material can contain a fluorene skeleton-containing phenol compound represented by the following general formula (3) (hereinafter sometimes referred to as “phenol compound 3”). The phenol compound used as a raw material may contain another phenol compound other than the phenol compound 3.

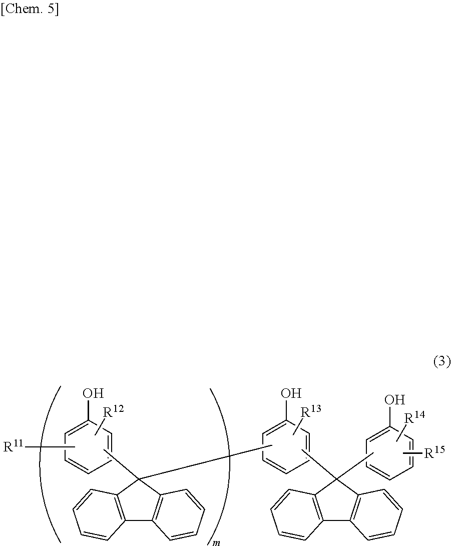

In the formula (3), R¹¹, R¹², R¹³, R¹⁴, and R¹⁵ are each independently a hydrogen atom or a hydrocarbon group having 1 to 8 carbon atoms, and may include a cyclic structure.

The main component of the phenol compound 3 may be a compound in which m in the general formula (3) is 0 (hereinafter also referred to as “compound 3-a”), or may contain a component in which m is 1 or more as a minor component. Examples of the compound 3-a include 9,9-bis(4-hydroxyphenyl)fluorene (BPFL).

The content of the compound 3-a in the phenol compound 3 may be 50 mass % or more. The content of the compound in which m is 1 or 2 in the phenol compound 3 (hereinafter also referred to as “compound 3-b”) may be 0.01 to 1.0 area %, 0.05 to 0.7 area %, or 0.07 to 0.5 area % when quantitative determination is performed in area % based on absorption at a wavelength of 272 nm by HPLC measurement.

In general formula (3), R¹¹, R¹², R¹³, R¹⁴, and R¹⁵ may each independently be a methyl group, an ethyl group, a tert-butyl group, a cyclohexyl group, a phenyl group, an indanyl group, or an α-methylbenzyl group, or may be a methyl group, a phenyl group, or an α-methylbenzyl group.

In order to adjust the introduction amount of the fluorene skeleton, a phenol compound other than the phenol compound 3 may be used in combination in an amount of 70 mass % or less with respect to the total amount of the phenol compound. Examples of such a phenol compound include dihydric phenol compounds such as bisphenol A, bisphenol F, bisphenol S, 4,4′-biphenol, tetramethyl bisphenol A, dimethyl bisphenol A, tetramethyl bisphenol F, dimethyl bisphenol F, tetramethyl bisphenol S, dimethyl bisphenol S, tetramethyl-4,4′-biphenol, dimethyl-4,4′-biphenol, 1-(4-hydroxyphenyl)-2-[4-(1,1-bis-(4-hydroxyphenyl)ethyl)phenyl]propane, 2,2′-methylene-bis(4-methyl-6-tert-butylphenol), 4,4′-butylidene-bis(3-methyl-6-tert-butylphenol), trishydroxyphenylmethane, resorcinol, and hydroquinone. One type of these phenol compounds can be used alone or two or more types thereof can be used in combination.

Examples of the difunctional epoxy resin include bisphenol type epoxy resins obtained from bisphenol A, bisphenol F, bisphenol AD, bisphenol S, tetramethyl bisphenol A, tetramethyl bisphenol F, tetramethyl bisphenol S, dimethyl bisphenol A, dimethyl bisphenol F, dimethyl bisphenol S, terpene diphenol, thiodiphenol, bisphenol fluorene, biscresol fluorene, dihydroxydiphenyl ether, and the like, biphenol type epoxy resins obtained from biphenol, tetramethyl biphenol, dimethyl biphenol, and the like, benzenediol type epoxy resins obtained from hydroquinone, methylhydroquinone, dibutylhydroquinone, resorcinol, methyl resorcinol, and the like, and naphthalene type epoxy resins obtained from dihydroxynaphthalene and the like. One type of these difunctional epoxy resins can be used alone or two or more types thereof can be used in combination.

As the difunctional epoxy resin, a difunctional epoxy resin having a fluorene skeleton (hereinafter also referred to as “difunctional epoxy resin F”) may be used. Thereby, the fluorene skeleton content in the component (C-F) can also be adjusted. Examples of the difunctional epoxy resin F include epoxy resins represented by the following general formula (4) (hereinafter also referred to as “epoxy resin 4”).

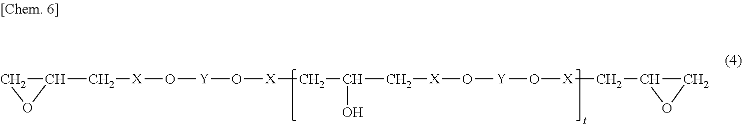

In the formula (4), X represents a divalent group represented by the following general formula (5), Y represents a divalent group represented by the following general formula (6), t represents the number of repetitions, and the average value (number average) is 0 to 5. t is preferably 0 to 3, and more preferably 0 to 1.

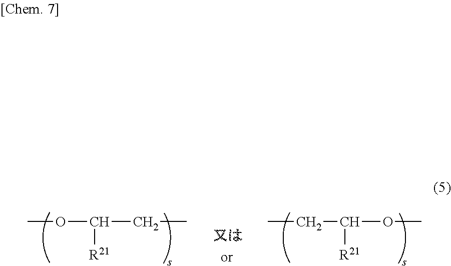

In the formula (5), R²¹ is a hydrogen atom or a methyl group, and s represents an integer of 0 to 3.

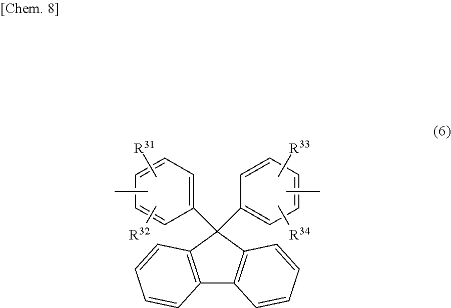

In the formula (6), R³¹, R³², R³³, and R³⁴ are each independently a hydrogen atom or a hydrocarbon group having 1 to 8 carbon atoms, and may include a cyclic structure.

The epoxy resin 4 may be an epoxy resin, which is obtained by a reaction of a bisphenol fluorene with epihalohydrin, and in which s in the general formula (4) is 0.

The epoxy equivalent of the difunctional epoxy resin F may be 230 to 500 g/eq, 230 to 400 g/eq, or 230 to 350 g/eq. In addition, the epoxy equivalent of the difunctional epoxy resin F is preferably lower than the epoxy equivalent of the intended component (C-F) by 100 g/eq or more, more preferably lower by 400 g/eq or more.

As the catalyst that can be used when the component (C-F) is produced, a known catalyst used in the production of an epoxy resin can be used, and examples thereof include phosphines such as triphenylphosphine and tris(2,6-dimethoxyphenyl)phosphine, quaternary phosphonium salts such as tetrabutylphosphonium benzotriazolate, tetra-n-butylphosphonium hexafluorophosphate, tetra-n-butylphosphonium o,o-diethylphosphorodithioate, methyltributylphosphonium dimethyl phosphate, tetra-n-butylphosphonium tetrafluoroborate, n-butyltriphenylphosphonium bromide, and ethyltriphenylphosphonium iodide, imidazoles such as 2-ethyl-4-methylimidazole and 2-phenylimidazole, quaternary ammonium salts such as tetramethylammonium chloride and tetraethylammonium bromide, tertiary amines such as triethylamine and benzyldimethylamine. Among them, phosphines or quaternary phosphonium salts are preferable. The amount of these catalysts used may be 0.005 to 1 part by mass or 0.01 to 0.5 parts by mass with respect to 100 parts by mass of the total amount of the phenol compound.

When the component (C-F) is produced, a reaction solvent can be used. As the reaction solvent, a non-reactive organic solvent can be used. Examples thereof include aromatic hydrocarbons such as benzene, toluene, xylene, ethylbenzene, and acetone; ketones such as methyl ethyl ketone, methyl butyl ketone, dipropyl ketone, cyclopentanone, and cyclohexanone, and ethers such as dialkyl ether, 2-ethoxyethyl ethyl ether, tetrahydrofuran, and dioxane. One type of these organic solvents can be used alone or two or more types thereof can be used in combination. Among the organic solvents described above, an organic solvent having a boiling point of 70 to 170° C. at normal pressure is preferable.

The amount of the organic solvent used can be 100 parts by mass or less with respect to 100 parts by mass of the total amount of the phenol compound and the difunctional epoxy resin.

As the epoxy resin thermosetting agent, a known curing agent having a function of thermally curing an epoxy resin can be used. Examples thereof include an amine-based curing agent, an acid anhydride curing agent, and a polyhydric phenolic curing agent.

Examples of the amine-based curing agent include aliphatic and alicyclic amines such as bis(4-aminocyclohexyl)methane, bis(aminomethyl)cyclohexane, m-xylylenediamine, isophoronediamine, and 3,9-bis(3-aminopropyl)-2,4,8,10-tetraspiro[5,5]undecane, aromatic amines such as meta-phenylenediamine, diaminodiphenylmethane, diaminodiphenylsulfone, and diaminoethylbenzene, tertiary amines such as benzyldimethylamine, 2,4,6-tris(dimethylaminomethyl)phenol, 1,8-diazabicyclo-(5,4,0)-undecene-7, and 1,5-azabicyclo-(4,3,0)-nonene-7, and salts thereof.

Examples of the acid anhydride-based curing agent include aromatic acid anhydrides such as phthalic anhydride, trimellitic anhydride, and pyromellitic anhydride, cyclic aliphatic acid anhydrides such as tetrahydrophthalic anhydride, methyltetrahydrophthalic anhydride, hexahydrophthalic anhydride, methylhexahydrophthalic anhydride, methylendomethylenetetrahydrophthalic anhydride, dodecenylsuccinic anhydride, and trialkyltetrahydrophthalic anhydride, and carboxylic acid dianhydrides such as 3,3′,4,4′-diphenylsulfonetetracarboxylic dianhydride, and 1,2,3,4-butanetetracarboxylic dianhydride.

Examples of the polyhydric phenolic curing agent include hydroxybenzenes such as catechol, resorcin, and hydroquinone, biphenols, binaphthols, bisphenols such as bisphenol F, bisphenol A, and bisphenol S, phenol novolacs, cresol novolacs, novolacs of dihydric phenols such as bisphenol A, alkylphenol novolacs, aralkylphenol novolacs, triazine ring-containing phenol novolacs, biphenyl aralkyl phenols, trishydroxyphenylmethane type novolacs, aralkyl naphthalene diols, and dicyclopentadiene polyphenols.

In the present embodiment, the below-described component (C2): a thermal cationic polymerization initiator can be used.

As the epoxy resin thermosetting agent, one type can be used alone or two or more types can be used in combination.

One embodiment of the adhesive film for circuit connection according to the present embodiment includes an adhesive film for circuit connection including a first adhesive layer (for example, corresponding to region P) containing electroconductive particles, a cured product of a photocurable resin component, and a first thermosetting resin component, and a second adhesive layer (for example, corresponding to region S) provided on the first adhesive layer and containing a second thermosetting resin component. In this adhesive film for circuit connection, the second thermosetting resin component can contain the component (C-F) and an epoxy resin thermosetting agent.

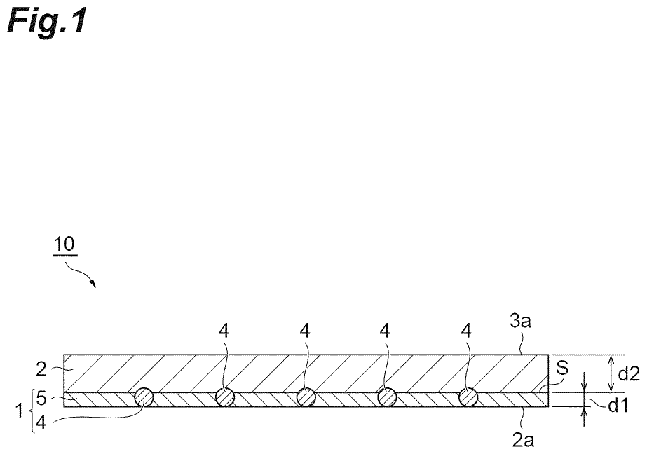

FIG. 1 is a schematic cross-sectional view showing one embodiment of an adhesive film for circuit connection according to the present embodiment. An adhesive film for circuit connection 10 (hereinafter sometimes simply referred to as “adhesive film 10”) shown in FIG. 1 includes a first adhesive layer 1 containing electroconductive particles 4 and an adhesive component 5 containing a cured product of a photocurable resin component and a (first) thermosetting resin component, and a second adhesive layer 2 provided on the first adhesive layer 1 and containing a (second) thermosetting resin component. In the adhesive film for circuit connection 10, the second thermosetting resin component contained in the second adhesive layer 2 can contain the fluorene skeleton-containing epoxy resin represented by the general formula (1) and the epoxy resin thermosetting agent.

Hereinafter, the adhesive film for circuit connection of the present embodiment will be described with reference to FIG. 1.

In the adhesive film 10, the electroconductive particles 4 are dispersed in the first adhesive layer 1. Therefore, the adhesive film 10 can be an adhesive film for circuit connection (anisotropic electroconductive adhesive film) having anisotropic electroconductivity. The adhesive film 10 may be interposed between a first circuit member having a first electrode and a second circuit member having a second electrode, and used to electrically connect the first electrode and the second electrode to each other by thermocompression bonding the first circuit member and the second circuit member.

### <First Adhesive Layer>

The first adhesive layer 1 contains electroconductive particles 4 (hereinafter sometimes referred to as “component (A)”), a cured product of a photocurable resin component (hereinafter sometimes referred to as “component (B)”), and a thermosetting resin component (hereinafter sometimes referred to as “component (C)”). The first adhesive layer 1 can be obtained, for example, by irradiating a composition layer formed of a composition containing the component (A), the component (B), and the component (C) with light energy, polymerizing the component contained in the component (B), and curing the component (B). The first adhesive layer 1 contains the component (A) and the adhesive component 5 containing the cured product of the component (B) and the component (C). The cured product of the component (B) may be a cured product obtained by completely curing the component (B), or may be a cured product obtained by curing a part of the component (B). The component (C) is a flowable component during circuit connection, and is, for example, an uncured curable resin component.

### Component (A): Electroconductive Particles

The component (A) is not particularly limited as long as it is a particle having electroconductivity, and may be a metal particle formed of a metal such as Au, Ag, Pd, Ni, Cu, or solder, an electroconductive carbon particle formed of electroconductive carbon, or the like. The component (A) may be a coated electroconductive particle including a core containing non-electroconductive glass, ceramic, plastic (polystyrene or the like), or the like, and a coating layer containing the metal or electroconductive carbon and coating the core. Among them, the component (A) is preferably a metal particle formed of a thermofusible metal, or a coated electroconductive particle including a core containing plastic and a coating layer containing a metal or electroconductive carbon and coating the core. Such a coated electroconductive particle facilitates deformation of the cured product of the thermosetting resin component by heating or pressurization, and therefore the contact area between the electrode and the component (A) can be increased when electrodes are electrically connected, and the electroconductivity between the electrodes can be further improved.

As the electroconductive particle, one having palladium plating can be used from the viewpoint of easily exhibiting low resistance to a circuit having a Ti surface. In this case, palladium plating can be provided on the outermost surface of the electroconductive particle. Specifically, it is possible to use an electroconductive particle in which Ni plating is applied to the surface of a plastic core body and displacement plating is applied to the outermost surface with Pd, and as such an electroconductive particle, from the viewpoint of preventing a short circuit between electroconductive particles, one having insulating fine particles supported on the surface may be used. From the viewpoint of making it easier to exhibit low resistance, in the process of applying Ni plating, a ceramic core material of 100 nm to 200 nm may be incorporated during plating, followed by Pd plating, and insulating fine particles may be supported as necessary.

The component (A) may be an insulation-coated electroconductive particle including the metal particle, the electroconductive carbon particle, or the coated electroconductive particle, and an insulating layer containing an insulating material such as a resin and coating the surface of the particle. When the component (A) is an insulation-coated electroconductive particle, even when the content of the component (A) is large, since the insulating layer is provided on the surface of the particle, occurrence of a short circuit due to contact between the components (A) can be suppressed, and insulation properties between adjacent electrode circuits can also be improved. As the component (A), one type of the above-described various electroconductive particles is used alone or two or more types thereof are used in combination.

The maximum particle diameter of the component (A) needs to be smaller than the minimum spacing of the electrodes (shortest distance between adjacent electrodes). The maximum particle diameter of the component (A) may be 1.0 μm or more, 2.0 μm or more, or 2.5 μm or more from the viewpoint of excellent dispersibility and electroconductivity. The maximum particle diameter of the component (A) may be 20 μm or less, 10 μm or less, or 5 μm or less from the viewpoint of excellent dispersibility and electroconductivity. In the present description, with respect to any 300 electroconductive particles (pcs), particle diameter measurement is performed by observation using a scanning electron microscope (SEM), and the largest obtained value is taken as the maximum particle diameter of the component (A). When the component (A) is not spherical, for example, when the component (A) has protrusions, the particle diameter of the component (A) is taken as the diameter of a circle circumscribing the electroconductive particle in an SEM image.

The average particle diameter of the component (A) may be 1.0 μm or more, 2.0 μm or more, or 2.5 μm or more from the viewpoint of excellent dispersibility and electroconductivity. The average particle diameter of the component (A) may be 20 μm or less, 10 μm or less, or 5 μm or less from the viewpoint of excellent dispersibility and electroconductivity. In the present description, with respect to any 300 electroconductive particles (pcs), particle diameter measurement is performed by observation using a scanning electron microscope (SEM), and the average value of the obtained particle diameters is taken as the average particle diameter.

In the first adhesive layer 1, the component (A) is preferably uniformly dispersed. The particle density of the component (A) in the adhesive film 10 may be 100 particles/mm² or more, 1000 particles/mm² or more, 3000 particles/mm² or more, or 5000 particles/mm² or more from the viewpoint of obtaining stable connection resistance. The particle density of the component (A) in the adhesive film 10 may be 100000 particles/mm² or less, 70000 particles/mm² or less, 50000 particles/mm² or less, or 30000 particles/mm² or less from a viewpoint of improving insulation properties between adjacent electrodes.

In the first adhesive layer 1, 80% or more, 90% or more, or 95% or more of the electroconductive particles may be in a state of being separated from other electroconductive particles. The proportion (monodispersion rate) at which electroconductive particles exist in a state separated from other adjacent electroconductive particles (monodispersed state) can be determined by observing the state of electroconductive particles in the adhesive layer using a metallographic microscope at a magnification of 200× and applying the following formula.

$$Monodispersion rate ( \% ) = ( Number of electroconductive particles in a monodispersed state in 0.16 {mm}^{2} / Number of electroconductive particles in 0.16 {mm}^{2} ) \times 100$$

The content of the component (A) may be 1 mass % or more, 5 mass % or more, or 10 mass % or more based on the total mass of the first adhesive layer from the viewpoint of further improving the electroconductivity. The content of the component (A) may be 60 mass % or less, 50 mass % or less, or 40 mass % or less based on the total mass of the first adhesive layer from the viewpoint of easily suppressing a short circuit. When the content of the component (A) is within the above range, the effect of the present invention tends to be remarkably exhibited. The content of the component (A) in the composition or the composition layer (based on the total mass of the composition or the composition layer) may be similar to the above range.

### Component (B): Photocurable Resin Component

The component (B) is not particularly limited as long as it is a resin component that is cured by light irradiation, but may be a resin component having radical curability from the viewpoint of more excellent connection resistance. The component (B) may contain, for example, a radically polymerizable compound (hereinafter sometimes referred to as “component (B1)”) and a photoradical polymerization initiator (hereinafter sometimes referred to as “component (B2)”). The component (B) can be a component formed of the component (B1) and the component (B2).

### Component (B1): Radically Polymerizable Compound

The component (B1) is a compound that is polymerized by a radical generated from the component (B2) by irradiation with light (for example, ultraviolet light). The component (B1) may be either a monomer or a polymer (or an oligomer) obtained by polymerizing one type or two or more types of monomers. As the component (B1), one type may be used alone or a plurality of types may be used in combination.

The component (B1) is a compound having a radically polymerizable group that reacts by a radical. Examples of the radically polymerizable group include a (meth)acryloyl group, a vinyl group, an allyl group, a styryl group, an alkenyl group, an alkenylene group, and a maleimide group. The number of radically polymerizable groups (the number of functional groups) of the component (B1) may be 2 or more from the viewpoint that a desired melt viscosity is easily obtained after polymerization, the connection resistance reduction effect is further improved, and connection reliability is more excellent, and may be 10 or less from the viewpoint that curing shrinkage during polymerization is suppressed. In addition, in order to balance the crosslink density and the curing shrinkage, in addition to a compound in which the number of radically polymerizable groups is within the above range, a compound in which the number of radically polymerizable groups is outside the above range may be used.

The component (B1) may contain, for example, a polyfunctional (di- or higher functional) (meth)acrylate from the viewpoint of suppressing the flow of the electroconductive particles. The polyfunctional (di- or higher functional) (meth)acrylate may be a difunctional (meth)acrylate, and the difunctional (meth)acrylate may be a difunctional aromatic (meth)acrylate.

Examples of the polyfunctional (meth)acrylate include aliphatic (meth)acrylates such as ethylene glycol di(meth)acrylate, diethylene glycol di(meth)acrylate, triethylene glycol di(meth)acrylate, tetraethylene glycol di(meth)acrylate, polyethylene glycol di(meth)acrylate, propylene glycol di(meth)acrylate, dipropylene glycol di(meth)acrylate, tripropylene glycol di(meth)acrylate, tetrapropylene glycol di(meth)acrylate, polypropylene glycol di(meth)acrylate, ethoxylated polypropylene glycol di(meth)acrylate, 1,3-butanediol di(meth)acrylate, 1,4-butanediol di(meth)acrylate, neopentyl glycol di(meth)acrylate, 3-methyl-1,5-pentanediol di(meth)acrylate, 1,6-hexanediol di(meth)acrylate, 2-butyl-2-ethyl-1,3-propanediol di(meth)acrylate, 1,9-nonanediol di(meth)acrylate, 1,10-decanediol di(meth)acrylate, glycerin di(meth)acrylate, tricyclodecanedimethanol (meth)acrylate, and ethoxylated 2-methyl-1,3-propanediol di(meth)acrylate, aromatic (meth)acrylates such as ethoxylated bisphenol A type di(meth)acrylate, propoxylated bisphenol A type di(meth)acrylate, ethoxylated propoxylated bisphenol A type di(meth)acrylate, ethoxylated bisphenol F type di(meth)acrylate, propoxylated bisphenol F type di(meth)acrylate, ethoxylated propoxylated bisphenol F type di(meth)acrylate, ethoxylated fluorene type di(meth)acrylate, propoxylated fluorene type di(meth)acrylate, and ethoxylated propoxylated fluorene type di(meth)acrylate, aliphatic (meth)acrylates such as trimethylolpropane tri(meth)acrylate, ethoxylated trimethylolpropane tri(meth)acrylate, propoxylated trimethylolpropane tri(meth)acrylate, ethoxylated propoxylated trimethylolpropane tri(meth)acrylate, pentaerythritol tri(meth)acrylate, ethoxylated pentaerythritol tri(meth)acrylate, propoxylated pentaerythritol tri(meth)acrylate, ethoxylated propoxylated pentaerythritol tri(meth)acrylate, pentaerythritol tetra(meth)acrylate, ethoxylated pentaerythritol tetra(meth)acrylate, propoxylated pentaerythritol tetra(meth)acrylate, ethoxylated propoxylated pentaerythritol tetra(meth)acrylate, ditrimethylolpropane tetraacrylate, and dipentaerythritol hexa(meth)acrylate; and aromatic epoxy (meth)acrylates such as bisphenol type epoxy (meth)acrylate, phenol novolac type epoxy (meth)acrylate, and cresol novolac type epoxy (meth)acrylate.

The content of the polyfunctional (di- or higher functional) (meth)acrylate may be, for example, 40 to 100 mass %, 50 to 100 mass %, or 60 to 100 mass % based on the total mass of the component (B1) from the viewpoint that both the connection resistance reduction effect and the suppression of flow of particles are achieved.

The component (B1) may further contain a monofunctional (meth)acrylate in addition to the polyfunctional (di- or higher functional) (meth)acrylate. Examples of the monofunctional (meth)acrylate include (meth)acrylic acid; aliphatic (meth)acrylates such as methyl (meth)acrylate, ethyl (meth)acrylate, butyl (meth)acrylate, isobutyl (meth)acrylate, tert-butyl (meth)acrylate, butoxyethyl (meth)acrylate, isoamyl (meth)acrylate, hexyl (meth)acrylate, 2-ethylhexyl (meth)acrylate, heptyl (meth)acrylate, octylheptyl (meth)acrylate, nonyl (meth)acrylate, decyl (meth)acrylate 2-hydroxyethyl (meth)acrylate, 2-hydroxypropyl (meth)acrylate, 3-chloro-2-hydroxypropyl (meth)acrylate, 2-hydroxybutyl (meth)acrylate, methoxypolyethylene glycol (meth)acrylate, ethoxypolyethylene glycol (meth)acrylate, methoxypolypropylene glycol (meth)acrylate, ethoxypolypropylene glycol (meth)acrylate, and mono (2-(meth)acryloyloxyethyl) succinate; aromatic (meth)acrylates such as benzyl (meth)acrylate, phenyl (meth)acrylate, o-biphenyl (meth)acrylate, 1-naphthyl (meth)acrylate, 2-naphthyl (meth)acrylate, phenoxyethyl (meth)acrylate, p-cumylphenoxyethyl (meth)acrylate, o-phenylphenoxyethyl (meth)acrylate, 1-naphthoxyethyl (meth)acrylate, 2-naphthoxyethyl (meth)acrylate, phenoxypolyethylene glycol (meth)acrylate, nonylphenoxypolyethylene glycol (meth)acrylate, phenoxypolypropylene glycol (meth)acrylate, 2-hydroxy-3-phenoxypropyl (meth)acrylate, 2-hydroxy-3-(o-phenylphenoxy) propyl (meth)acrylate, 2-hydroxy-3-(1-naphthoxy) propyl (meth)acrylate, and 2-hydroxy-3-(2-naphthoxy) propyl (meth)acrylate; (meth)acrylates having an epoxy group such as glycidyl (meth)acrylate, (meth)acrylates having an alicyclic epoxy group such as 3,4-epoxycyclohexylmethyl (meth)acrylate, and (meth)acrylates having an oxetanyl group such as (3-ethyloxetane-3-yl)methyl (meth)acrylate.

The content of the monofunctional (meth)acrylate may be, for example, 0 to 60 mass %, 0 to 50 mass %, or 0 to 40 mass % based on the total mass of the component (B1).

The cured product of the component (B) may have, for example, a polymerizable group that reacts by means other than a radical. The polymerizable group that reacts by means other than a radical may be, for example, a cationically polymerizable group that reacts by a cation. Examples of the cationically polymerizable group include an epoxy group such as a glycidyl group, an alicyclic epoxy group such as an epoxy cyclohexylmethyl group, and an oxetanyl group such as an ethyl oxetanylmethyl group. The cured product of the component (B) having a polymerizable group that reacts by means other than a radical can be introduced by using, as the component (B), for example, a (meth)acrylate having a polymerizable group that reacts by means other than a radical, such as a (meth)acrylate having an epoxy group, a (meth)acrylate having an alicyclic epoxy group, or a (meth)acrylate having an oxetanyl group. The mass ratio of the (meth)acrylate having a polymerizable group that reacts by means other than a radical to the total mass of the component (B1) (the mass of the (meth)acrylate having a polymerizable group that reacts by means other than a radical (charged amount)/the total mass of the component (B1) (charged amount)) may be, for example, 0 to 0.7, 0 to 0.5, or 0 to 0.3 from the viewpoint of improving reliability.

The component (B1) may contain another radically polymerizable compound in addition to the polyfunctional (di- or higher functional) and the monofunctional (meth)acrylates. Examples of another radically polymerizable compound include a maleimide compound, a vinyl ether compound, an allyl compound, a styrene derivative, an acrylamide derivative, and a nadimide derivative. The content of another radically polymerizable compound may be, for example, 0 to 40 mass % based on the total mass of the component (B1).

### Component (B2): Photoradical Polymerization Initiator

The component (B2) is a photopolymerization initiator that generates a radical by irradiation with light having a wavelength in the range of 150 to 750 nm, preferably with light having a wavelength in the range of 254 to 405 nm, more preferably with light having a wavelength of 365 nm (for example, ultraviolet light). As the component (B2), one type may be used alone or a plurality of types may be used in combination.

The component (B2) is decomposed by light to generate a free radical. That is, the component (B2) is a compound that generates a radical by application of light energy from the outside. The component (B2) may be a compound having a structure such as an oxime ester structure, a bisimidazole structure, an acridine structure, an a-aminoalkylphenone structure, an aminobenzophenone structure, an N-phenylglycine structure, an acylphosphine oxide structure, a benzyldimethylketal structure, or an α-hydroxyalkylphenone structure. As the component (B2), one type may be used alone or a plurality of types may be used in combination. The component (B2) may be a compound having at least one type of structure selected from the group consisting of an oxime ester structure, an α-aminoalkylphenone structure, and an acylphosphine oxide structure from the viewpoint that a desired melt viscosity is easily obtained, and the connection resistance reduction effect is more excellent.

Specific examples of the compound having an oxime ester structure include 1-phenyl-1,2-butanedione-2-(o-methoxycarbonyl)oxime, 1-phenyl-1,2-propanedione-2-(o-1-phenyl-1,2-propanedione-2-(0-methoxycarbonyl)oxime, ethoxycarbonyl)oxime, 1-phenyl-1,2-propanedione-2-o-benzoyloxime, 1,3-diphenylpropanetrione-2-(o-ethoxycarbonyl)oxime, 1-phenyl-3-ethoxypropanetrione-2-(o-benzoyl)oxime, 1,2-octanedione, 1-[4-(phenylthio)phenyl-, 2-(o-benzoyloxime)], ethanone, 1-[9-ethyl-6-(2-methylbenzoyl)-9H-carbazol-3-yl]-, and 1-(o-acetyloxime).

Specific examples of the compound having an α-aminoalkylphenone structure include 2-methyl-1-[4-(methylthio)phenyl]-2-morpholinopropane-1-one and 2-benzyl-2-dimethylamino-1-morpholinophenyl)-butanone-1.

Specific examples of the compound having an acylphosphine oxide structure include bis(2,6-dimethoxybenzoyl)-2,4,4-trimethyl-pentylphosphine oxide, bis(2,4,6,-trimethylbenzoyl)-phenylphosphine oxide, and 2,4,6-trimethylbenzoyl-diphenylphosphine oxide.

The content of the component (B2) may be, for example, 0.1 to 10 parts by mass, 0.3 to 7 parts by mass, or 0.5 to 5 parts by mass with respect to 100 parts by mass of the component (B1) from the viewpoint of suppressing the flow of the electroconductive particles.

The content of the cured product of the component (B) may be 1 mass % or more, 5 mass % or more, or 10 mass % or more based on the total mass of the first adhesive layer from the viewpoint of suppressing the flow of the electroconductive particles. The content of the cured product of the component (B) may be 50 mass % or less, 40 mass % or less, or 30 mass % or less based on the total mass of the first adhesive layer from the viewpoint of exhibiting low resistance in low-pressure mounting. When the content of the cured product of the component (B) is within the above range, the effect of the present invention tends to be remarkably exhibited. The content of the component (B) in the composition or the composition layer (based on the total mass of the composition or the composition layer) may be similar to the above range.

### Component (C): Thermosetting Resin Component

The component (C) may contain, for example, a cationically polymerizable compound (hereinafter sometimes referred to as “component (C1)”) and a thermal cationic polymerization initiator (hereinafter sometimes referred to as “component (C2)”). The component (C) can be a component formed of the component (C1) and the component (C2). The first thermosetting resin component and the second thermosetting resin component mean thermosetting resin components contained in the first adhesive layer and the second adhesive layer, respectively. The types, combinations, and contents of the components (for example, the component (C1), the component (C2), and the like) contained in the first thermosetting resin component and the second thermosetting resin component may be the same as or different from each other.

### Component (C1): Cationically Polymerizable Compound

The component (C1) is a compound that is crosslinked by reacting with the component (C2) by heat. The component (C1) means a compound having no radically polymerizable group that reacts by a radical, and the component (C1) is not included in the component (B1). The component (C1) may be a compound having one or more ring-opening polymerizable cyclic ether groups in the molecule from the viewpoint that the connection resistance reduction effect is further improved, and the connection reliability is more excellent. As the component (C1), one type may be used alone or a plurality of types may be used in combination. The compound having one or more ring-opening polymerizable cyclic ether groups in the molecule may be, for example, at least one type selected from the group consisting of an oxetane compound and an alicyclic epoxy compound. The component (C1) preferably contains both of at least one type of oxetane compound and at least one type of alicyclic epoxy compound from the viewpoint that a desired melt viscosity is easily obtained.

The oxetane compound as the component (C1) can be used without particular limitation as long as it is a compound having an oxetanyl group and having no radically polymerizable group. Examples of a commercially available product of the oxetane compound include ETERNACOLL OXBP (trade name, manufactured by Ube Industries, Ltd.), OXSQ, OXT-121, OXT-221, OXT-101, and OXT-212 (trade name, manufactured by Toagosei Co., Ltd.). One type of these may be used alone or a plurality of types may be used in combination.

The alicyclic epoxy compound as the component (C1) can be used without particular limitation as long as it is a compound having an alicyclic epoxy group (for example, an epoxycyclohexyl group) and having no radically polymerizable group. Examples of a commercially available product of the alicyclic epoxy compound include EHPE 3150, EHPE 3150CE, CEL 8010, CEL 2021P, and CEL 2081 (trade name, manufactured by Daicel Corporation). One type of these may be used alone or a plurality of types may be used in combination.

The first adhesive layer 1, the composition for forming the first adhesive layer 1, and the composition layer may contain the component (C-F) as the component (C1). In this case, the content of the component (C-F) may be 5 to 30 mass %, 8 to 25 mass %, or 11 to 20 mass % based on the total amount of the component (C1).

### Component (C2): Thermal Cationic Polymerization Initiator

The component (C2) is a thermal polymerization initiator that generates an acid or the like by heating to initiate polymerization. The component (C2) may be a salt compound formed of a cation and an anion. Examples of the component (C2) include onium salts such as a sulfonium salt, a phosphonium salt, an ammonium salt, a diazonium salt, an iodonium salt, and an anilinium salt each having an anion such as BF₄⁻, BR₄⁻ (R represents a phenyl group substituted with two or more fluorine atoms or two or more trifluoromethyl groups), PF₆⁻, SbF₆⁻, or AsF₆⁻. When the component (C1) contains an epoxy resin, the above-described epoxy resin thermosetting agent may be used as the component (C2). As the component (C2), one type may be used alone or a plurality of types may be used in combination.

From the viewpoint of storage stability, the component (C2) may be, for example, a salt compound having an anion containing boron as a constituent element, that is, BF₄⁻ or BR₄⁻ (R represents a phenyl group substituted with two or more fluorine atoms or two or more trifluoromethyl groups). The anion containing boron as a constituent element may be BR₄⁻, and more specifically, may be tetrakis(pentafluorophenyl)borate.

The onium salt as the component (C2) may be, for example, an anilinium salt since it has resistance to a substance that can cause curing inhibition against cationic curing. Examples of the anilinium salt compound include N,N-dialkylanilinium salts such as a N,N-dimethylanilinium salt and a N,N-diethylanilinium salt,

The component (C2) may be an anilinium salt having an anion containing boron as a constituent element. Examples of a commercially available product of such a salt compound include CXC-1821 (trade name: manufactured by King Industries, Inc.).

The content of the component (C2) may be, for example, 0.1 to 25 parts by mass, 1 to 20 parts by mass, 3 to 18 parts by mass, or 5 to 15 parts by mass with respect to 100 parts by mass of the component (C1) from the viewpoint of ensuring the formability and curability of the adhesive film for forming the first adhesive layer.

The content of the component (C) may be 5 mass % or more, 10 mass % or more, 15 mass % or more, or 20 mass % or more based on the total mass of the first adhesive layer from a viewpoint of ensuring the curability of the adhesive film for forming the first adhesive layer. The content of the component (C) may be 70 mass % or less, 60 mass % or less, 50 mass % or less, or 40 mass % or less based on the total mass of the first adhesive layer from the viewpoint of ensuring the formability of the adhesive film for forming the first adhesive layer. When the content of the component (C) is within the above range, the effect of the present invention tends to be remarkably exhibited. The content of the component (C) in the composition or the composition layer (based on the total mass of the composition or the composition layer) may be similar to the above range.

### [Other Components]

The first adhesive layer 1 may further contain other components in addition to the component (A), the cured product of the component (B), and the component (C). Examples of other components include a film-forming component (hereinafter sometimes referred to as “component (D)”), a coupling agent (hereinafter sometimes referred to as “component (E)”), and a filler (hereinafter sometimes referred to as “component (F)”).

Examples of the component (D) include a phenoxy resin, a polyester resin, a polyamide resin, a polyurethane resin, a polyester urethane resin, an acrylic rubber, and an epoxy resin (solid at 25° C.). One type of these may be used alone or a plurality of types may be used in combination. When the composition containing the component (A), the component (B), and the component (C) further contains the component (D), a composition layer (further, the first adhesive layer 1) can be easily formed from the composition. Among these, the component (D) may be, for example, a phenoxy resin.

The weight average molecular weight (Mw) of the component (D) may be, for example, 5000 to 200000, 10000 to 100000, 20000 to 80,000, or 40000 to 60000 from the viewpoint of resin removability during mounting. Here, Mw means a value obtained by measurement with gel permeation chromatography (GPC) and conversion using a calibration curve based on standard polystyrene.

The content of the component (D) may be 1 mass % or more, 5 mass % or more, 10 mass % or more, or 20 mass % or more, and may be 70 mass % or less, 60 mass % or less, 50 mass % or less, or 40 mass % or less based on the total mass of the first adhesive layer. The content of the component (D) in the composition or the composition layer (based on the total mass of the composition or the composition layer) may be similar to the above range.

Examples of the component (E) include a silane coupling agent having an organic functional group such as a (meth)acryloyl group, a mercapto group, an amino group, an imidazole group, or an epoxy group, a silane compound such as tetraalkoxysilane, a tetraalkoxy titanate derivative, and a polydialkyl titanate derivative. One type of these may be used alone or a plurality of types may be used in combination. When the first adhesive layer 1 contains the component (E), adhesiveness can be further improved. The component (E) may be, for example, a silane coupling agent. The content of the component (E) may be 0.1 to 10 mass % based on the total mass of the first adhesive layer. The content of the component (E) in the composition or the composition layer (based on the total mass of the composition or the composition layer) may be similar to the above range.

Examples of the component (F) include a non-electroconductive filler (for example, non-electroconductive particles). The component (F) may be either an inorganic filler or an organic filler. Examples of the inorganic filler include metal oxide fine particles such as silica fine particles, alumina fine particles, silica-alumina fine particles, titania fine particles, and zirconia fine particles; and inorganic fine particles such as metal nitride fine particles. Examples of the organic filler include organic fine particles such as silicone fine particles, methacrylate butadiene styrene fine particles, acrylic silicone fine particles, polyamide fine particles, and polyimide fine particles. One type of these may be used alone or a plurality of types may be used in combination. The component (F) may be, for example, silica fine particles. The content of the component (F) may be 0.1 to 10 mass % based on the total mass of the first adhesive layer. The content of the component (F) in the composition or the composition layer (based on the total mass of the composition or the composition layer) may be similar to the above range.

### [Other Additives]

The first adhesive layer 1 may further contain other additives such as an ion scavenger, a softener, an accelerator, a degradation inhibitor, a colorant, a flame retardant, and a thixotropic agent. The content of other additives may be, for example, 0.1 to 10 mass % based on the total mass of the first adhesive layer. The content of other additives in the composition or the composition layer (based on the total mass of the composition or the composition layer) may be similar to the above range.

The thickness d1 of the first adhesive layer 1 may be, for example, 5 μm or less. The thickness d1 of the first adhesive layer 1 may be 4.5 μm or less or 4.0 μm or less. When the thickness d1 of the first adhesive layer 1 is 5 μm or less, electroconductive particles during circuit connection can be more efficiently captured. The thickness d1 of the first adhesive layer 1 may be, for example, 0.1 μm or more, 0.5 μm or more, or 0.7 μm or more. The thickness d1 of the first adhesive layer 1 can be determined, for example, by sandwiching an adhesive film between two sheets of glass (thickness: about 1 mm), casting with a resin composition containing 100 g of a bisphenol A type epoxy resin (trade name: jER811, manufactured by Mitsubishi Chemical Corporation) and 10 g of a curing agent (trade name: EPOMOUNT hardener, manufactured by Refine Tec Ltd.), then polishing the cross section using a polishing machine, and measuring the thickness using a scanning electron microscope (SEM, trade name: SE-8020, manufactured by Hitachi High-Tech Science Corporation). In addition, as shown in FIG. 1, when some of the electroconductive particles 4 are exposed (for example, protrude toward the second adhesive layer 2 side) from the surface of the first adhesive layer 1, the distance from the surface 2a of the first adhesive layer 1 on the side opposite to the second adhesive layer 2 side to the boundary S between the first adhesive layer 1 and the second adhesive layer 2 located at the separated portion of the adjacent electroconductive particles 4, 4 (distance indicated by dl in FIG. 1) is the thickness of the first adhesive layer 1, and the exposed portion of the electroconductive particle 4 is not included in the thickness of the first adhesive layer 1. The length of the exposed portion of the electroconductive particle 4 may be, for example, 0.1 μm or more and 5 μm or less.

### <Second Adhesive Layer>

The second adhesive layer 2 contains the component (C). The component (C) (that is, the second thermosetting resin component) in the second adhesive layer 2 can contain the fluorene skeleton-containing epoxy resin (component (C-F)) represented by the general formula (1) and the epoxy resin thermosetting agent. The component (C) may contain the component (C1) other than the component (C-F) as the component (C1). Furthermore, the component (C) may contain the component (C2) described above as the epoxy resin thermosetting agent. As the component (C1) and the component (C2), components similar to the component (C1) and the component (C2) used in the component (C) (that is, the first thermosetting resin component) in the first adhesive layer 1 are used. The second thermosetting resin component may be the same as or different from the first thermosetting resin component.

The component (C-F) contained in the second adhesive layer 2 may have a weight molecular weight of 5000 to 8000 from the viewpoint of obtaining HAST resistance even in low-pressure mounting and from the viewpoint of transferability.

The component (C-F) may have a softening point of 85 to 105° C. from the viewpoint of obtaining HAST resistance even under low-pressure mounting and from the viewpoint of transferability.

The second adhesive layer 2 preferably contains at least one type of oxetane compound as the component (C1) other than the component (C-F) from the viewpoint of maintaining fluidity during curing.

From the viewpoint of maintaining high reliability, the content of the component (C-F) in the second adhesive layer 2 may be 10 to 40 mass %, 13 to 37 mass %, or 16 to 34 mass % based on the total mass of the component (C-F) and the component (C1) other than the component (C-F).

The content of the component (C) may be 5 mass % or more, 10 mass % or more, 15 mass % or more, or 20 mass % or more based on the total mass of the second adhesive layer from the viewpoint of maintaining reliability. The content of the component (C) may be 70 mass % or less, 60 mass % or less, 50 mass % or less, or 40 mass % or less based on the total mass of the second adhesive layer from the viewpoint of preventing resin seepage problem in a reel which is one aspect of the supply form.

The second adhesive layer 2 may further contain other components and other additives in the first adhesive layer 1. Preferred aspects of other components and other additives are similar to those of the first adhesive layer 1.

The content of the component (D) may be 1 mass % or more, 5 mass % or more, or 10 mass % or more, and may be 80 mass % or less, 60 mass % or less, or 40 mass % or less based on the total mass of the second adhesive layer.

The content of the component (E) may be 0.1 to 10 mass % based on the total mass of the second adhesive layer.

The content of the component (F) may be 1 mass % or more, 5 mass % or more, or 10 mass % or more, and may be 70 mass % or less, 50 mass % or less, or 30 mass % or less based on the total mass of the second adhesive layer.

The content of other additives may be, for example, 0.1 to 10 mass % based on the total mass of the second adhesive layer.

The thickness d2 of the second adhesive layer 2 may be appropriately set according to, for example, the height of the electrode of the circuit member to be bonded. The thickness d2 of the second adhesive layer 2 may be 5 μm or more or 7 μm or more, and may be 15 μm or less or 11 μm or less from the viewpoint that the space between electrodes can be sufficiently filled to seal the electrodes and better connection reliability can be obtained. The thickness d2 of the second adhesive layer 2 can be determined by, for example, a method similar to the method for measuring the thickness d1 of the first adhesive layer 1. In addition, when some of the electroconductive particles 4 are exposed (for example, protrude toward the second adhesive layer 2 side) from the surface of the first adhesive layer 1, the distance from the surface 3a of the second adhesive layer 2 on the side opposite to the first adhesive layer 1 side to the boundary S between the first adhesive layer 1 and the second adhesive layer 2 located at the separated portion of the adjacent electroconductive particles 4, 4 (distance indicated by d2 in FIG. 1) is the thickness of the second adhesive layer 2.

The thickness of the adhesive film 10 (the total thickness of all layers constituting the adhesive film 10, in FIG. 1, the sum of the thickness d1 of the first adhesive layer 1 and the thickness d2 of the second adhesive layer 2) may be, for example, 5 μm or more or 8 μm or more, and may be 30 μm or less or 20 μm or less.

When the adhesive film for circuit connection of the present embodiment has the region P and the region S described above, the range of the region P in the thickness direction of the film can be set in the same manner as the thickness of the first adhesive layer described above. The content of each component in the region P can also be set in the same manner as in the first adhesive layer. The range of the region S in the thickness direction of the film can be set in the same manner as the thickness of the second adhesive layer described above. The content of each component in the region S can also be set in the same manner as in the second adhesive layer.

The minimum melt viscosity of the adhesive film 10 is 450 to 1600 Pa·s. The minimum melt viscosity of the adhesive film 10 may be 500 Pa·s or more, 600 Pa·s or more, 700 Pa·s or more, or 800 Pa·s or more. When the minimum melt viscosity of the adhesive film 10 is 450 Pa·s or more, deformation of the plastic substrate during thermocompression bonding can be suppressed, and occurrence of circuit disconnection can be prevented. The minimum melt viscosity of the adhesive film 10 may be 1500 Pa·s or less, 1400 Pa·s or less, 1300 Pa·s or less, 1200 Pa·s or less, 1100 Pa·s or less, or 1000 Pa·s or less. When the minimum melt viscosity of the adhesive film 10 is 1600 Pa·s or less, it is possible to suppress a decrease in resin removability during circuit connection, so that it is possible to reduce connection resistance between the opposing electrodes of the circuit connection structure and to ensure good conduction characteristics. The minimum melt viscosity of the adhesive film can be determined, for example, by the following method.

### (Method for Measuring Minimum Melt Viscosity)

Each adhesive film is laminated with a laminator so as to have a thickness of 500 μm or more to obtain a laminate. The release-treated PET is peeled off from the obtained laminate, and cut into 10.0 mm×10.0 mm to obtain a measurement sample. The minimum melt viscosity of the obtained measurement sample is measured using a viscoelasticity measurement apparatus (trade name: ARES-G2, manufactured by TA Instruments, heating rate: 10° C./min).

In the adhesive film 10, the second adhesive layer 2 is usually thicker than the first adhesive layer 1. Therefore, the minimum melt viscosity of the adhesive film 10 tends to vary depending on the second adhesive layer 2. The minimum melt viscosity of the adhesive film 10 can be adjusted, for example, by adjusting the type, content, and the like of a constituent component (particularly, the component (D)) contained in the second adhesive layer 2. The minimum melt viscosity of the adhesive film 10 can also be adjusted, for example, by using a material having a small particle diameter as the component (F). When a material having a small particle diameter is used as the component (F), the minimum melt viscosity of the adhesive film 10 tends to increase.

In the adhesive film 10, the electroconductive particles 4 are dispersed in the first adhesive layer 1. Therefore, the adhesive film 10 is an anisotropic electroconductive adhesive film having anisotropic electroconductivity. The adhesive film 10 is interposed between a first circuit member having a first electrode and a second circuit member having a second electrode, and used to electrically connect the first electrode and the second electrode to each other by thermocompression bonding the first circuit member and the second circuit member.

According to the adhesive film 10, even when the circuit members are connected to each other with a low pressure, it is possible to sufficiently ensure conduction between the opposing electrodes of the circuit connection structure and to sufficiently maintain insulation properties between adjacent circuits. In addition, according to this adhesive film 10, it is possible to obtain a circuit connection structure having sufficient HAST resistance in stabilizing the connection resistance between the opposing electrodes. Such an adhesive film for circuit connection can be suitably used for COP mounting. More specifically, it can be suitably used for connection between a plastic substrate on which a circuit electrode is formed in an organic EL display and an IC chip such as a driver IC.

Although the adhesive film of the present embodiment has been described above, the present invention is not limited to the above embodiment.

The adhesive film may be formed of, for example, two layers of the first adhesive layer and the second adhesive layer, and may be formed of three or more layers including two layers of the first adhesive layer and the second adhesive layer. The adhesive film may be configured to further include, for example, a third adhesive layer provided on a side of the first adhesive layer opposite to the second adhesive layer.

The third adhesive layer contains the component (C). The component (C1) and the component (C2) used in the component (C) (that is, the third thermosetting resin component) in a third adhesive layer are similar to the component (C1) and the component (C2) used in the component (C) (that is, the first thermosetting resin component) in the first adhesive layer 1, and thus, a detailed description is omitted here. The third thermosetting resin component may be the same as or different from the first thermosetting resin component. The third thermosetting resin component may be the same as or different from the second thermosetting resin component.

The third thermosetting resin component may contain the component (C-F) as the component (C1). In this case, the content of the component (C-F) may be 5 to 30 mass %, 8 to 27 mass %, or 11 to 24 mass % based on the total amount of the component (C1).

The content of the component (C) may be 5 mass % or more, 10 mass % or more, 15 mass % or more, or 20 mass % or more based on the total mass of the third adhesive layer from the viewpoint of imparting good transferability and peeling resistance. The content of the component (C) may be 70 mass % or less, 60 mass % or less, 50 mass % or less, or 40 mass % or less based on the total mass of the third adhesive layer from the viewpoint of imparting good half-cut properties and blocking resistance (suppression of resin seepage from a reel).

The third adhesive layer may further contain other components and other additives in the first adhesive layer 1. Preferred aspects of other components and other additives are similar to those of the first adhesive layer 1.

The content of the component (D) may be 10 mass % or more, 20 mass % or more, or 30 mass % or more, and may be 80 mass % or less, 70 mass % or less, or 60 mass % or less based on the total mass of the third adhesive layer.

The content of the component (E) may be 0.1 to 10 mass % based on the total mass of the third adhesive layer.

The content of the component (F) may be 1 mass % or more, 3 mass % or more, or 5 mass % or more, and may be 50 mass % or less, 40 mass % or less, or 30 mass % or less based on the total mass of the third adhesive layer.

The content of other additives may be, for example, 0.1 to 10 mass % based on the total mass of the third adhesive layer.

The thickness of the third adhesive layer may be appropriately set according to, for example, the minimum melt viscosity of the adhesive film, or the height of the electrode of the circuit member to be bonded. The thickness of the third adhesive layer is preferably smaller than the thickness d2 of the second adhesive layer 2. The thickness of the third adhesive layer may be 0.2 μm or more and 3.0 μm or less from the viewpoint that the space between electrodes can be sufficiently filled to seal the electrodes and better connection reliability can be obtained. The thickness of the third adhesive layer can be determined by, for example, a method similar to the method for measuring the thickness d1 of the first adhesive layer 1.

The adhesive film for circuit connection of the above embodiment may be an anisotropic electroconductive adhesive film or an electroconductive adhesive film having no anisotropic electroconductivity.

### <Method for Producing Adhesive Film for Circuit Connection>

The method for producing an adhesive film for circuit connection of an embodiment may include, for example, a step of forming a first adhesive layer by irradiating a composition layer formed of a composition containing the component (A), the component (B), and the component (C) (first thermosetting resin component) and, if necessary, other components with light (first step), and a step of laminating a second adhesive layer containing the component (C) (second thermosetting resin component) and, if necessary, other components on the first adhesive layer (second step). The production method may further include a step of laminating a third adhesive layer containing the component (C) (third thermosetting resin component) and, if necessary, other components on a layer of the first adhesive layer on a side opposite to the second adhesive layer (third step). In this case, the second step may be performed first, or the third step may be performed first. When the third step is performed first, the third adhesive layer is laminated on the side of the first adhesive layer opposite to the side on which the second adhesive layer is to be laminated.

In the first step, for example, first, a composition containing the component (A), the component (B), and the component (C), and other components to be added as necessary is dissolved or dispersed by stirring and mixing, kneading, or the like in an organic solvent to prepare a varnish composition (varnish-like first adhesive composition). Thereafter, the varnish composition is applied onto the release-treated base material using a knife coater, a roll coater, an applicator, a comma coater, a die coater, or the like, and then the organic solvent is volatilized by heating to form a composition layer formed of the composition on the base material. At this time, the thickness of the first adhesive layer (first adhesive film) finally obtained can be adjusted by adjusting the application amount of the varnish composition. Subsequently, the composition layer formed of the composition is irradiated with light to cure the component (B) in the composition layer to form a first adhesive layer on the base material. The first adhesive layer can be referred to as a first adhesive film.

The organic solvent used in the preparation of the varnish composition is not particularly limited as long as it has a property of being able to uniformly dissolve or disperse each component. Examples of such an organic solvent include toluene, acetone, methyl ethyl ketone, methyl isobutyl ketone, ethyl acetate, propyl acetate, and butyl acetate. These organic solvents can be used alone or two or more types thereof can be used in combination. Stirring and mixing or kneading in the preparation of the varnish composition can be performed using, for example, a stirrer, a grinding machine, a three-roll mill, a ball mill, a bead mill, a homodisper, or the like.

The base material is not particularly limited as long as it has heat resistance capable of withstanding heating conditions when the organic solvent is volatilized. As such a base material, for example, a base material (for example, a film) formed of stretched polypropylene (OPP), polyethylene terephthalate (PET), polyethylene naphthalate, polyethylene isophthalate, polybutylene terephthalate, polyolefin, polyacetate, polycarbonate, polyphenylene sulfide, polyamide, polyimide, cellulose, ethylene-vinyl acetate copolymer, polyvinyl chloride, polyvinylidene chloride, synthetic rubber-based, a liquid crystal polymer, or the like can be used.

Heating condition when volatilizing the organic solvent from the varnish composition applied to the base material can be appropriately set according to the organic solvent to be used and the like. The heating condition may be, for example, 40 to 120° C. for 0.1 to 10 minutes.

A part of the solvent may remain in the first adhesive layer without being removed. The content of the solvent in the first adhesive layer may be, for example, 10 mass % or less based on the total mass of the first adhesive layer.

For light irradiation in the curing step, it is preferable to use irradiation light (for example, ultraviolet light) having a wavelength in the range of 150 to 750 nm. Light irradiation can be performed using, for example, a low-pressure mercury lamp, an intermediate-pressure mercury lamp, a high-pressure mercury lamp, an ultra-high pressure mercury lamp, a xenon lamp, a metal halide lamp, an LED light source, or the like. The integrated light amount of the light irradiation can be appropriately set, and may be, for example, 500 to 3000 mJ/cm².

The second step is a step of laminating a second adhesive layer on the first adhesive layer. In the second step, for example, first, a second adhesive layer is formed on the base material in the same manner as in the first step except that the component (C) and other components to be added as necessary are used and light irradiation is not performed to obtain a second adhesive film. Then, the second adhesive layer can be laminated on the first adhesive layer by bonding the first adhesive film and the second adhesive film. In the second step, the second adhesive layer can also be laminated on the first adhesive layer by, for example, applying a varnish composition (varnish-like second adhesive composition) obtained using the component (C) and other components to be added as necessary onto the first adhesive layer, and volatilizing the organic solvent.

Examples of the method for bonding the first adhesive film and the second adhesive film include methods such as hot pressing, roll lamination, and vacuum lamination. The lamination can be performed, for example, under a temperature condition of 0 to 80° C.

A part of the solvent may remain in the second adhesive layer without being removed. The content of the solvent in the second adhesive layer may be, for example, 10 mass % or less based on the total mass of the second adhesive layer.

The third step is a step of laminating a third adhesive layer on a layer of the first adhesive layer on a side opposite to the second adhesive layer. In the third step, for example, first, a third adhesive layer is formed on the base material in the same manner as in the second step to obtain a third adhesive film. Then, the third adhesive layer can be laminated on a layer of the first adhesive layer on a side opposite to the second adhesive layer by bonding the third adhesive film on a side of the first adhesive film opposite to the second adhesive film. In the third step, the third adhesive layer can also be laminated on the first adhesive layer by, for example, applying a varnish composition (varnish-like third adhesive composition) onto a layer of the first adhesive layer on a side opposite to the second adhesive layer, and volatilizing the organic solvent in the same manner as in the second step. The bonding method and the conditions thereof are similar to those in the second step.

A part of the solvent may remain in the third adhesive layer without being removed. The content of the solvent in the third adhesive layer may be, for example, 10 mass % or less based on the total mass of the third adhesive layer.

### <Circuit Connection Structure and Method for Producing the Same>

Hereinafter, a circuit connection structure obtained using the above-described adhesive film for circuit connection 10 as a circuit connection material and a method for producing the circuit connection structure will be described.

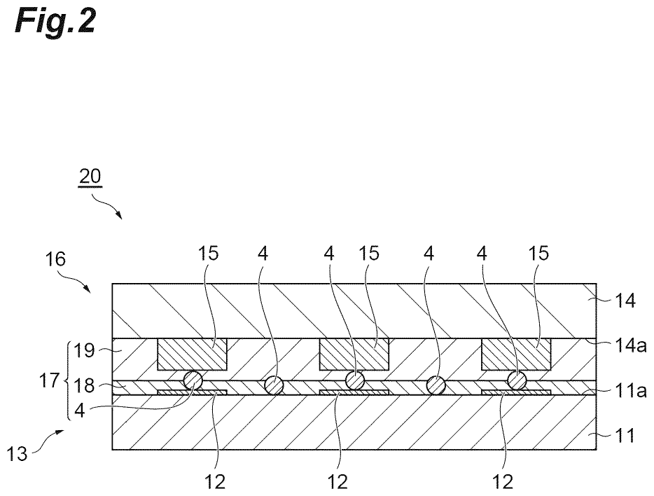

FIG. 2 is a schematic cross-sectional view showing one embodiment of a circuit connection structure. As shown in FIG. 2, a circuit connection structure 20 includes a first circuit member 13 having a first circuit board 11 and a first electrode 12 formed on a main surface 11a of the first circuit board 11, a second circuit member 16 having a second circuit board 14 and a second electrode 15 formed on a main surface 14a of the second circuit board 14, and a circuit connection portion 17 disposed between the first circuit member 13 and the second circuit member 16 and electrically connecting the first electrode 12 and the second electrode 15 to each other.

The first circuit member 13 and the second circuit member 16 may be the same as or different from each other. The first circuit member 13 and the second circuit member 16 may each be a glass substrate or a plastic substrate on which a circuit electrode is formed; a printed wiring board; a ceramic wiring board; a flexible wiring board; an IC chip such as a driver IC; or the like. The first circuit board 11 and the second circuit board 14 may each be formed of an inorganic material such as a semiconductor, glass, or ceramic, an organic material such as polyimide or polycarbonate, a composite material such as glass/epoxy, or the like. The first circuit board 11 may be a plastic substrate. The first circuit member 13 may be, for example, a plastic substrate (a plastic substrate formed of an organic material such as polyimide, polycarbonate, polyethylene terephthalate, or a cycloolefin polymer) on which a circuit electrode is formed, and the second circuit member 16 may be, for example, an IC chip such as a driver IC. A plastic substrate on which an electrode is formed may be one in which a display region is formed, for example, by regularly arranging pixel driving circuits such as organic TFTs or a plurality of organic EL elements R, G, and B in a matrix pattern on the plastic substrate.

The first electrode 12 and the second electrode 15 may be electrodes containing a metal such as gold, silver, tin, ruthenium, rhodium, palladium, osmium, iridium, platinum, copper, aluminum, molybdenum, or titanium, an oxide such as indium tin oxide (ITO), indium zinc oxide (IZO), or indium gallium zinc oxide (IGZO), or the like. The first electrode 12 and the second electrode 15 may be electrodes formed by laminating two or more types of these metals, oxides, and the like. The electrode formed by laminating two or more types may have two or more layers or three or more layers. When the first circuit member 13 is a plastic substrate, the first electrode 12 may be an electrode having a titanium layer on the outermost surface. The first electrode 12 and the second electrode 15 may be circuit electrodes or bump electrodes. At least one of the first electrode 12 and the second electrode 15 may be a bump electrode. FIG. 2 shows an aspect in which the first electrode 12 is a circuit electrode and the second electrode 15 is a bump electrode.

The circuit connection portion 17 includes a cured product of the adhesive film 10 described above. The circuit connection portion 17 may be formed of a cured product of the adhesive film 10 described above. The circuit connection portion 17 has, for example, a first region 18 that is located on the first circuit member 13 side in a direction in which the first circuit member 13 and the second circuit member 16 oppose each other (hereinafter “opposing direction”) and is formed of a cured product of the component (B) and a cured product of the component (C) and the like, excluding the electroconductive particles 4 in the above-described first adhesive layer, a second region 19 that is located on the second circuit member 16 side in the opposing direction and is formed of a cured product of the component (C) and the like in the above-described second adhesive layer, and electroconductive particles 4 that are interposed at least between the first electrode 12 and the second electrode 15 and electrically connect the first electrode 12 and the second electrode 15 to each other. The circuit connection portion 17 need not have two clear regions between the first region 18 and the second region 19 as shown in FIG. 2, and a cured product derived from the first adhesive layer and a cured product derived from the second adhesive layer may be mixed to form one region.

Examples of the circuit connection structure include a flexible organic electroluminescent color display (organic EL display) in which a plastic substrate with regularly arranged organic EL elements is connected to a drive circuit element serving as a driver for video display, and a touch panel in which a plastic substrate with regularly arranged organic EL elements is connected to a position input element such as a touch pad. The circuit connection structure can be applied to various monitors such as a smartphone, a tablet, a television, a navigation system of a vehicle, and a wearable terminal; furniture; home appliance; daily necessities; and the like.

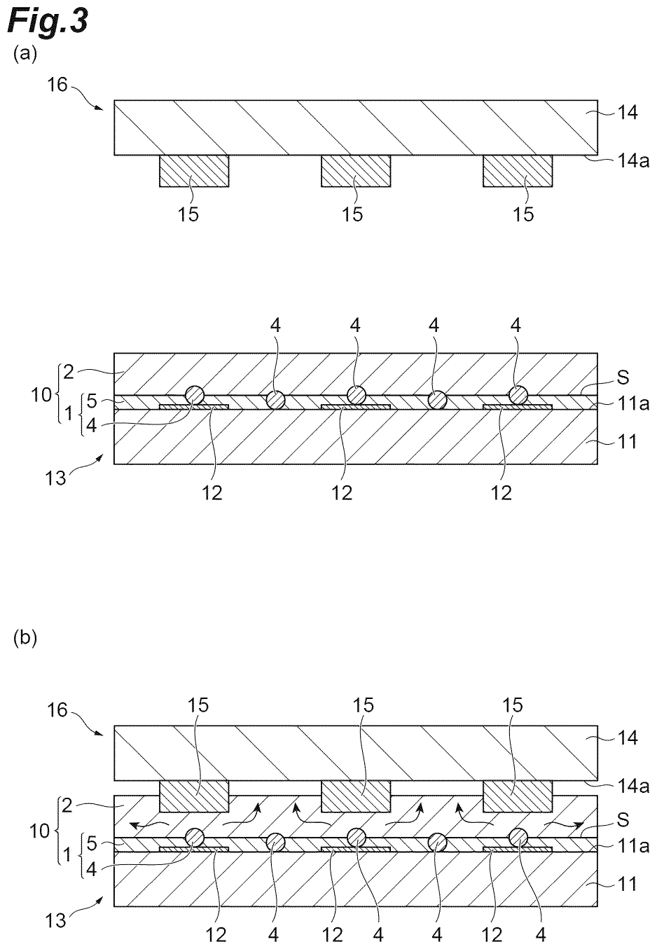

FIG. 3 is a schematic cross-sectional view showing one embodiment of a method for producing a circuit connection structure. FIGS. 3(a) and 3(b) are schematic cross-sectional views showing each step. As shown in FIG. 3, the method for producing a circuit connection structure 20 includes a step of interposing the adhesive film 10 between a first circuit member 13 having a first electrode 12 and a second circuit member 16 having a second electrode 15, and thermocompression bonding the first circuit member 13 and the second circuit member 16 to electrically connect the first electrode 12 and the second electrode 15 to each other.

Specifically, as shown in FIG. 3(a), first, a first circuit member 13 including a first circuit board 11 and a first electrode 12 formed on a main surface 11a of the first circuit board 11, and a second circuit member 16 including a second circuit board 14 and a second electrode 15 formed on a main surface 14a of the second circuit board 14 are prepared.

Next, the first circuit member 13 and the second circuit member 16 are disposed such that the first electrode 12 and the second electrode 15 oppose each other, and the adhesive film 10 is disposed between the first circuit member 13 and the second circuit member 16. For example, as shown in FIG. 3(a), the adhesive film 10 is laminated on the first circuit member 13 such that the first adhesive layer 1 side opposes the main surface 11a of the first circuit board 11. Next, the second circuit member 16 is disposed on the first circuit member 13 laminated with the adhesive film 10 such that the first electrode 12 on the first circuit board 11 and the second electrode 15 on the second circuit board 14 oppose each other.

Then, as shown in FIG. 3(b), the first circuit member 13 and the second circuit member 16 are thermocompression bonded to each other by pressurizing the first circuit member 13 and the second circuit member 16 in the thickness direction while heating the first circuit member 13, the adhesive film 10, and the second circuit member 16. At this time, as indicated by an arrow in FIG. 3(b), since the second adhesive layer 2 has a flowable uncured thermosetting component, the second adhesive layer 2 flows so as to fill voids between the second electrodes 15, and is cured by the heating. As a result, the first electrode 12 and the second electrode 15 are electrically connected to each other via the electroconductive particles 4, and the first circuit member 13 and the second circuit member 16 are bonded to each other, so that the circuit connection structure 20 shown in FIG. 2 can be obtained. In the method for producing the circuit connection structure 20 of the present embodiment, since it can be said that a part of the first adhesive layer 1 is cured by light irradiation, the flow of the electroconductive particles in the first adhesive layer 1 is suppressed, the first adhesive layer 1 hardly flows during the thermocompression bonding, and the electroconductive particles are efficiently captured between the opposing electrodes, so that the connection resistance between the opposing first electrode 12 and second electrode 15 is reduced. In addition, when the thickness of the first adhesive layer is 5 μm or less, there is a tendency that the electroconductive particles during circuit connection can be more efficiently captured.

The heating temperature in the case of thermocompression bonding can be appropriately set, and may be, for example, 50 to 190° C. The pressure to be applied is not particularly limited as long as it does not damage the adherend, but in the case of COP mounting, for example, the pressure calculated on an area basis at the bump electrode may be 0.1 to 50 MPa, 40 MPa or less, or 0.1 to 40 MPa. In the case of COG mounting, for example, the pressure calculated on an area basis at the bump electrode may be 10 to 100 MPa. The heating and pressurization time may be in the range of 0.5 to 120 seconds.

The present invention also relates to the following matters.

[1] An adhesive film for circuit connection including a thermosetting resin component and electroconductive particles, wherein the thermosetting resin component contains a fluorene skeleton-containing epoxy resin represented by the following general formula (1) and an epoxy resin thermosetting agent:

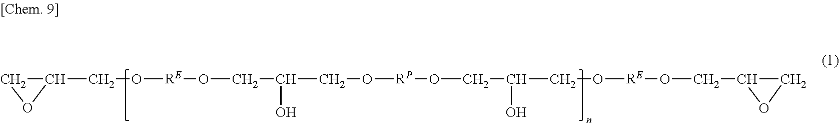

in the formula (1), R^{E} is a skeleton residue derived from an epoxy resin, R′ is a skeleton residue derived from a phenol compound having a fluorene skeleton, and n represents the number of repetitions.

[2] The adhesive film for circuit connection according to [1], wherein the fluorene skeleton-containing epoxy resin has a weight average molecular weight of 5000 to 8000.

[3] The adhesive film for circuit connection according to [1] or [2], wherein the fluorene skeleton-containing epoxy resin has a softening point of 85 to 105° C.

[4] The adhesive film for circuit connection according to any one of [1] to [3], wherein the electroconductive particles are unevenly distributed on one surface side of the film.

[5] An adhesive film for circuit connection, including a first adhesive layer containing electroconductive particles, a cured product of a photocurable resin component, and a first thermosetting resin component, and a second adhesive layer provided on the first adhesive layer and containing a second thermosetting resin component, wherein the second thermosetting resin component contains a fluorene skeleton-containing epoxy resin represented by the following general formula (1) and an epoxy resin thermosetting agent:

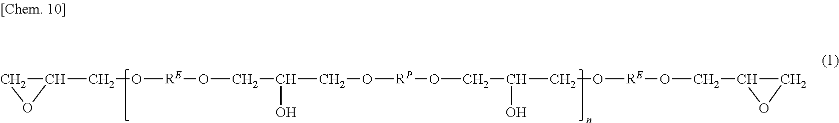

in the formula (1), R^{E} is a skeleton residue derived from an epoxy resin, R^{P} is a skeleton residue derived from a phenol compound having a fluorene skeleton, and n represents the number of repetitions.

[6] The adhesive film for circuit connection according to [5], wherein the fluorene skeleton-containing epoxy resin has a weight average molecular weight of 5000 to 8000.

[7] The adhesive film for circuit connection according to [5] or [6], wherein the fluorene skeleton-containing epoxy resin has a softening point of 85 to 105° C.

[8] A method for producing a circuit connection structure, the method including steps of interposing the adhesive film for circuit connection according to any one of [1] to [7] between a first circuit member having a first electrode and a second circuit member having a second electrode; and thermocompression bonding the first circuit member and the second circuit member to electrically connect the first electrode and the second electrode to each other.

[9] A circuit connection structure, including a first circuit member having a first electrode, a second circuit member having a second electrode, and a circuit connection portion disposed between the first circuit member and the second circuit member and configured to electrically connect the first electrode and the second electrode to each other, wherein the circuit connection portion includes a cured product of the adhesive film for circuit connection according to any one of [1] to [7].

### EXAMPLES

Hereinafter, the present invention will be described more specifically with reference to examples. However, the present invention is not limited to these examples.

### [Production of Electroconductive Particles]

After Ni plating was applied to the surfaces of polystyrene particles, displacement plating with Pd was applied to the outermost surfaces to produce electroconductive particles having an average particle diameter of 3.2 μm.

### [Production of First Adhesive Layer and Second Adhesive Layer]

In the production of a first adhesive layer and a second adhesive layer, the following materials were used.

### Component (A): Electroconductive Particles

A-1: Electroconductive particles produced above

### Component (B): Photocurable Resin Component

### Component (B1): Radically Polymerizable Compound

B1-1: A-BPEF-70T (ethoxylated fluorene di(meth) acrylate (difunctional), trade name, manufactured by Shin-Nakamura Chemical Co., Ltd.), one obtained by dilution with toluene to a nonvolatile content of 70 mass % was used.
B1-2: Ripoxy VR-90 (bisphenol A type epoxy (meth)acrylate (difunctional) (vinyl ester resin), trade name, manufactured by Showa Denko K.K.)

### Component (B2): Photoradical Polymerization Initiator

B2-1: Irgacure OXE-02 (ethanone, 1-[9-ethyl-6-(2-methylbenzoyl)-9H-carbazol-3-yl]-, 1-(0-acetyloxime), trade name, manufactured by BASF SE), one obtained by dilution with MEK to a nonvolatile content of 10 mass % was used.

### Component (C): Thermosetting Resin Component

### Component (C1): Cationically Polymerizable Compound

C1-1: ETERNACOLL OXBP (3-ethyl-3-hydroxymethyloxetane, trade name, manufactured by Ube Industries, Ltd.)
C1-2: EHPE 3150 (1,2-epoxy-4-(2-oxiranyl)cyclohexane adduct of 2,2-bis(hydroxymethyl)-1-butanol, trade name, manufactured by Daicel Corporation)
C1-3: OX-SQ TX-100 (poly({3-[(3-ethyl-3-oxetanyl) methoxy]propyl}silsesquioxane) derivative, trade name, manufactured by Toagosei Co., Ltd.)
C1-4: CELLOXIDE 2021P (3′,4′-epoxycyclohexylmethyl-3,4-epoxycyclohexanecarboxylate, trade name, manufactured by Daicel Corporation)
C1-5: YL980 (bisphenol A type epoxy resin, epoxy equivalent: 180 to 190, weight average molecular weight: 362, trade name, manufactured by Mitsubishi Chemical Corporation)
C1-6: jER1007 (epoxy resin, epoxy equivalent: 180 to 190, weight average molecular weight: 10,000, trade name, manufactured by Mitsubishi Chemical Corporation), one obtained by dilution with an organic solvent to a nonvolatile content of 70 mass %, was used.
C1-7: jER1010 (bisphenol A type solid epoxy resin, epoxy equivalent: 3000 to 5000, weight average molecular weight: 40000, trade name, manufactured by Mitsubishi Chemical Corporation)

### Component (C-F): Fluorene Skeleton-Containing Epoxy Resin Represented by General Formula (1)

C-F-1: TOPR-300 (high Tg type epoxy resin, epoxy equivalent: 900 to 1,000, weight average molecular weight: 6700, softening point: 91° C., trade name, manufactured by Nippon Steel Chemical & Materials Co., Ltd.), one obtained by dilution with MEK to a nonvolatile content of 60 mass %, was used.

### Component (C2): Thermal Cationic Polymerization Initiator (Epoxy Resin Thermosetting Agent)

C2-1: CXC-1821 (trade name, manufactured by King Industries, Inc.)

### Component (D): Film-Forming Component

D-1: FX293 (fluorene skeleton-containing phenoxy resin, weight average molecular weight: 32,000, glass transition temperature: 152° C., trade name, manufactured by Nippon Steel Chemical & Materials Co., Ltd.), one obtained by dilution with MEK to a nonvolatile content of 35 mass % was used.

### Component (E): Coupling Agent

E-1: KBM-303 (ethyltrimethoxysilane, trade name, manufactured by Shin-Etsu Chemical Co., Ltd.)

### Component (F): Filler

F-1: Admafine SE2050 (silica fine particles, trade name, manufactured by Admatechs Company Limited)

The weight average molecular weights of the fluorene skeleton-containing epoxy resin and the fluorene skeleton-containing phenoxy resin were measured under the following conditions using gel permeation chromatography (GPC).
Detector: L-2490-RI manufactured by Hitachi High-Tech Science Corporation
Column: Gelpack GL-R440+R450+R400M
Flow rate: 2.05 ml/min
Concentration: 5 mg/ml
Injection amount: 200 μl
Column temperature: 40° C.
Eluent: THF
Standard sample: polystyrene

The softening point of the fluorene skeleton-containing epoxy resin was measured under the following conditions using a thermomechanical analyzer (TMA).
Thermomechanical analyzer: TMA-7100 manufactured by Hitachi High-Tech Science Corporation, Penetration (needle insertion, Φ1 mm) mode
Heating rate: 10° C./min
Load: 98.1 mN

### <Production of First Adhesive Layer>

A composition was obtained by mixing the materials shown in Table 1 at the composition ratios (the numerical values in Table 1 mean nonvolatile contents) shown in Table 1, and then applied onto a release-treated PET (polyethylene terephthalate) film while applying a magnetic field, and an organic solvent and the like were dried with hot air at 70° C. for 5 minutes to obtain each composition layer formed of the composition containing respective components. The application was performed so that the thickness of the composition layer after drying was 3 to 4 μm. Thereafter, each composition layer was irradiated with light (UV irradiation: metal halide lamp, integrated light amount: 1000 to 3000 mJ/cm²) to produce a first adhesive layer in which electroconductive particles were dispersed. The thickness here was measured using a contact type thickness meter.

In a case where the thickness of the layer formed of the first adhesive composition or the adhesive layer is smaller than the thickness (diameter) of the electroconductive particle, when the thickness of the layer is measured using a contact type thickness meter, the thickness of the electroconductive particle is reflected, and the thickness of the region where the electroconductive particle is present is measured. Therefore, an adhesive film having a two-layer structure in which a first adhesive layer and a second adhesive layer were laminated was produced, and then the thickness of the first adhesive layer located at the separated portion of the adjacent electroconductive particles was measured using a scanning electron microscope by the above-described method (paragraph 0106).

TABLE 1

| | | Composition P-1 |
|---|---|---|
| Component (A) | A-1 | 45 |
| Component (B1) | B1-1 | 20 |
| | B1-2 | 10 |
| Component (B2) | B2-1 | 0.5 |
| Component (C1) | C1-1 | 25 |
| | C1-2 | 10 |
| | C1-3 | 5 |
| Component (C2) | C2-1 | 4 |
| Component (D) | D-1 | 30 |
| Component (E) | E-1 | 3 |

### <Production of Second Adhesive Layer>

A composition was obtained by mixing the materials shown in Table 2 at the composition ratios (the numerical values in Table 2 mean nonvolatile contents) shown in Table 2, and then applied onto a release-treated PET (polyethylene terephthalate) film, and an organic solvent and the like were dried with hot air at 70° C. for 5 minutes to produce each second composition layer formed of the composition containing respective components. The application was performed so that the thickness of the composition layer after drying was 8 to 9 μm. The thickness here was measured using a contact type thickness meter. In this manner, the second adhesive layer was produced on the PET film.

TABLE 2

| | | Composition | Composition | Composition | Composition | Composition | Composition | Composition | Composition |
|---|---|---|---|---|---|---|---|---|---|
| | | S-1 | S-2 | S-3 | S-4 | S-5 | S-6 | S-7 | S-8 |
| Component | C1-1 | 20 | 20 | 20 | 20 | 20 | 20 | 20 | 20 |
| (C1) | C1-2 | 10 | 10 | 10 | 10 | 10 | 10 | 10 | 10 |
| | C1-4 | 20 | 20 | 20 | 20 | 20 | 20 | 20 | 20 |
| | C1-5 | — | — | — | — | — | 40 | — | — |
| | C1-6 | — | — | — | — | — | — | 40 | — |
| | C1-7 | — | — | — | — | — | — | — | 40 |
| | C-F-1 | 40 | 50 | 30 | — | — | — | — | — |
| Component | C2-1 | 4 | 4 | 4 | 4 | 4 | 4 | 4 | 4 |
| (C2) | | | | | | | | | |
| Component | D-1 | 18 | 18 | 18 | 58 | 38 | 18 | 18 | 18 |
| (D) | | | | | | | | | |
| Component | E-1 | 4 | 4 | 4 | 4 | 4 | 4 | 4 | 4 |
| (E) | | | | | | | | | |
| Component | F-1 | 80 | 80 | 80 | 80 | 80 | 80 | 80 | 80 |
| (F) | | | | | | | | | |

### Examples 1 to 3 and Comparative Examples 1 to 5

### [Production of Adhesive Film]

An adhesive film having the configuration shown in Table 3 was produced using the first adhesive layer and the second adhesive layer produced above. For example, in the adhesive film of Example 1, the first adhesive layer formed of the composition P-1 was bonded to the second adhesive layer formed of the composition S-1 while applying a temperature of 50 to 60° C. to obtain the adhesive film of Example 1. With respect to the adhesive films of Examples 2 to 3 and Comparative Examples 1 to 5, adhesive films having the configurations shown in Table 3 were produced in the same manner as in Example 1.

With respect to the adhesive films of Examples 1 to 3 and Comparative Examples 1 to 5, the projected particle density was measured and found to be about 18000 particles/mm².

### [Evaluation of Circuit Connection Structure]

### <Production of Circuit Connection Structure>

As a first circuit member, an IC chip (0.9 mm×20.3 mm, thickness: 0.3 mm, size of bump electrode: 70 μm×12 μm, space between bump electrodes: 12 μm, bump electrode thickness: 9 μm) in which bump electrodes were arranged in two rows in a staggered manner was prepared. In addition, as a second circuit member, one in which a wiring pattern (pattern width: 17 μm, space between electrodes: 7 μm) of Ti: 50 nm/Al: 400 nm was formed on a surface of a polyimide substrate (200H, manufactured by DU PONT-TORAY CO., LTD.) (38 mm×28 mm, thickness: 0.05 mm) was prepared.

A circuit connection structure was produced using each of the adhesive films of Examples 1 to 3 and Comparative Examples 1 to 5. The adhesive film was cut into a width of 2.0 mm, and the adhesive film was disposed on the first circuit member such that the first adhesive layer was in contact with the first circuit member. The adhesive film was bonded to the first circuit member by heating and pressurizing for 2 seconds under the conditions of 70° C. and 0.98 MPa (10 kgf/cm²) using a thermocompression bonding apparatus (BS-17U, manufactured by OHASHI ENGINEERING Co., Ltd.) formed of a stage made of a ceramic heater and a tool (8 mm×50 mm), and the release film of the adhesive film on the side opposite to the first circuit member was peeled off. Subsequently, the bump electrode of the first circuit member and the wiring pattern of the second circuit member were aligned, and then heated and pressurized for 5 seconds under the conditions of a connection condition of 180° C. and a pressure calculated on an area basis at the bump electrode of 25 MPa via Teflon (registered trademark) having a thickness of 50 μm as a buffer material using a heat tool of 8 mm×45 mm, and the second adhesive layer of the adhesive film was bonded to the second circuit member to produce each circuit connection structure.

### (Evaluation of Connection Resistance)

The initial connection resistance (conduction resistance) of the produced circuit connection structure was measured by a four-terminal method. A multimeter (7461A, manufactured by ADC Corporation) was used for the measurement. The potential difference was measured at 14 arbitrary points, and the average value thereof was obtained. The average value of the potential difference was converted to a connection resistance value and evaluated according to the following criteria. The results are shown in Table 3.
A: The connection resistance value is less than 1.0Ω.
B: The connection resistance value is 1.0Ω or more and less than 3.0Ω.
C: The connection resistance value is 3.0Ω or more.

After a high-temperature and high-humidity test in which the produced circuit connection structure was stored at 110° C. and 85% RH for 32 hours was performed, a connection resistance value was calculated in the same manner as described above, and evaluation was performed according to the following criteria. The results are shown in Table 3.
A: The connection resistance value is less than 1.0Ω.
B: The connection resistance value is 1.0Ω or more and less than 3.0Ω.
C: The connection resistance value is 3.0Ω or more.

### [Evaluation of Back Transfer Resistance of Adhesive Film]

### (Production of Reel Body of Adhesive Film (Tape))

The adhesive film (first adhesive layer/second adhesive layer/PET film) obtained above was cut to a width of 0.6 mm by a roll-to-roll slit equipment, and an adhesive tape was wound around a reel component (winding core outer diameter: 66 mm, plastic molded article) at a length of 100 m. At this time, the adhesive film was wound so that the first adhesive layer faced the winding core side (inside) and the PET film faced the outside. Reel side plates (thickness: 2.0 mm) were provided on both sides of the winding core, and a gap distance between the reel side plates and the wound body of the adhesive tape was in a range of about 0.1 mm to 0.5 mm on each of the left and right sides.

### [Evaluation of Back Transfer Resistance]

The reel body was fixed in a vertical position, a 75 g weight was suspended from the tip, and the reel body was left in a constant temperature chamber (relative humidity: 40 to 60%) at a temperature of 30° C. for 6 hours. Thereafter, the adhesive tape was pulled out from the reel body using TENSILON (trade name, manufactured by A&D Company, Limited) at a rate of 1 m/min, observed with a microscope, and the back transfer resistance was evaluated according to the following criteria.
OK: No back transfer of the adhesive film (peeling between the second adhesive layer and the PET film) of 5 mm or more was observed over a length of 100 m.
NG: Back transfer of the adhesive film of 5 mm or more was observed in a length of 100 m.

TABLE 3

| | | | | Comparative | Comparative | Comparative | Comparative | Comparative |
|---|---|---|---|---|---|---|---|---|
| | Example 1 | Example 2 | Example 3 | Example 1 | Example 2 | Example 3 | Example 4 | Example 5 |
| First adhesive | Composition | Composition | Composition | Composition | Composition | Composition | Composition | Composition |
| layer (region P) | P-1 | P-1 | P-1 | P-1 | P-1 | P-1 | P-3 | P-1 |
| Second adhesive | Composition | Composition | Composition | Composition | Composition | Composition | Composition | Composition |
| layer (region S) | S-1 | S-2 | S-3 | S-4 | S-5 | S-6 | S-7 | S-8 |
| Connection | A | A | A | B | A | A | A | A |
| resistance | | | | | | | | |
| (initial) | | | | | | | | |
| Connection | A | A | A | C | B | C | C | C |
| resistance | | | | | | | | |
| (after high- | | | | | | | | |
| temperature and | | | | | | | | |
| high-humidity test) | | | | | | | | |
| Transferability | OK | OK | OK | OK | NG | NG | OK | OK |

### REFERENCE SIGNS LIST

1 First adhesive layer
2 Second adhesive layer
4 Electroconductive particle
5 Adhesive component
10 Adhesive film for circuit connection (adhesive film)
11 First circuit board
12 First electrode (circuit electrode)
13 First circuit member
14 Second circuit board
15 Second electrode (bump electrode)
16 Second circuit member
17 Circuit connection portion

1. An adhesive film for circuit connection, comprising a thermosetting resin component and electroconductive particles, wherein
the thermosetting resin component contains a fluorene skeleton-containing epoxy resin represented by the following general formula (1) and an epoxy resin thermosetting agent: 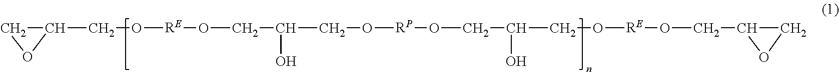
in the formula (1), R^{E} is a skeleton residue derived from an epoxy resin, R^{P} is a skeleton residue derived from a phenol compound having a fluorene skeleton, and n represents the number of repetitions.

2. The adhesive film for circuit connection according to claim 1, wherein the fluorene skeleton-containing epoxy resin has a weight average molecular weight of 5000 to 8000.

3. The adhesive film for circuit connection according to claim 1, wherein the fluorene skeleton-containing epoxy resin has a softening point of 85 to 105° C.

4. The adhesive film for circuit connection according to claim 1, wherein the electroconductive particles are unevenly distributed on one surface side of the film.

5. An adhesive film for circuit connection, comprising a first adhesive layer containing electroconductive particles, a cured product of a photocurable resin component, and a first thermosetting resin component, and a second adhesive layer provided on the first adhesive layer and containing a second thermosetting resin component, wherein
the second thermosetting resin component contains a fluorene skeleton-containing epoxy resin represented by the following general formula (1) and an epoxy resin thermosetting agent: 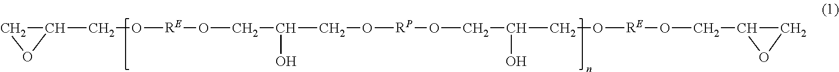
in the formula (1), R^{E} is a skeleton residue derived from an epoxy resin, R^{P} is a skeleton residue derived from a phenol compound having a fluorene skeleton, and n represents the number of repetitions.

6. The adhesive film for circuit connection according to claim 5, wherein the fluorene skeleton-containing epoxy resin has a weight average molecular weight of 5000 to 8000.

7. The adhesive film for circuit connection according to claim 5, wherein the fluorene skeleton-containing epoxy resin has a softening point of 85 to 105° C.

8. A method for producing a circuit connection structure, the method comprising steps of: interposing the adhesive film for circuit connection according to claim 1 between a first circuit member having a first electrode and a second circuit member having a second electrode; and thermocompression bonding the first circuit member and the second circuit member to electrically connect the first electrode and the second electrode to each other.

9. A circuit connection structure, comprising:
a first circuit member having a first electrode;
a second circuit member having a second electrode; and
a circuit connection portion disposed between the first circuit member and the second circuit member and configured to electrically connect the first electrode and the second electrode to each other, wherein
the circuit connection portion includes a cured product of the adhesive film for circuit connection according to claim 1.
